(19) United States
(12) Patent Application Publication
(10) Pub. No.: US 2019/0162798 A1
(43) Pub. Date: May 30, 2019

(54) ATOMIC FORCIPES AND NUCLEAR MAGNETIC ISOTOPE SEPARATION METHOD AND APPARATUS

(71) Applicant: Peter Robert Butzloff, Saint David, ME (US)

(72) Inventor: Peter Robert Butzloff, Saint David, ME (US)

(21) Appl. No.: 15/826,425

(22) Filed: Nov. 29, 2017

(51) Int. Cl. G01R 33/028; G01R 33/28; C01B 32/182; C01B 33/40; G01R 33/44

(52) U.S. Cl. CPC G01R 33/028; G01R 33/28; C01B 32/182; B01D 59/00; G01R 33/44; C01B 2204/04; C01B 33/405

(57) ABSTRACT

Atomic forcipes is a nanomechanical magnetoelectric element having an insulator, an atom-thick conductive graphene sheet suspended as a heterostructure onto the insulator, and a gallery between the insulator and the graphene sheet. Atomic forcipes can be actuated acoustically or electromagnetically. Activation generates a chemical potential of directionally enhanced chemical reaction rate. Atomic forcipes can be formed by selecting enhanced graphene having a particle size, providing piezoelectric smectite clay of the particle size, combining graphene particles with clay, adding a compatibilizer, and irradiating with ultrasound, UV, or microwaves. Isotope separation apparatus and methods are supported by atomic forcipes. A method by mixing an aqueous phase suspension of atomic forcipes with nuclear magnetic isotope (NMI) ions, applying ultrasound to promote NMI ion intercalation, applying ultraviolet light to generate free radicals on the NMI ions, and extracting enriched NMI ions from the piezoelectric sheets. Another method employs nuclear spin using nuclear magnetic stiction.

### CROSS-REFERENCE TO RELATED APPLICATIONS

This application is related to U.S. application entitled “APPARATUS AND METHOD FOR ATOMIC FORCIPES BODY MACHINE INTERFACE,” Attorney Docket B054-8020, filed concurrently, on even date herewith, which is co-pending with the present application, and which hereby is incorporated by reference in its entirety.

### FIELD OF THE INVENTION

The present invention generally relates to apparatus and methods for isotope separation and, particularly, to isotope separation using metamaterials.

### BACKGROUND OF THE INVENTION

In a globally aging population, the diseases associated with the increased lifetime of human beings are now rapidly increasing. Methods of reducing the cost and time to market for the distribution of essential pure non-radioactive isotopes in common use for biological, medical healthcare, and material tracer applications, have yet to be optimized.

Past isotope separations began by using mass differences between chemically identical isotopes by applying energy intensive cooling, heating, or centrifugal techniques, broadly classified as kinetic isotope effects or KIE. For example, microwave energy can be used to efficiently vaporize and then re-condense materials in repeated cycles. Freezing can also be used, as the lighter isotopes tend to freeze before the heavy isotopes can find a place in the crystal lattice. These methods are effective but take multiple iterations to perform significant concentration of the chosen nuclear species. For example, silicon isotope separation using multiple distillation plates demonstrates the severe economic and energy costs of processing that are involved in the use of the kinetic isotope separation effect for increasingly important technological quantum logic devices.

More recently, it was found that specific isotopes express a nuclear spin that can interact with their electrons to create a nuclear magnetic interaction broadly classified as magnetic isotope effects or MIE. This emerging area of applied science has focused on the use of DC currents and strong static magnetic fields, which has resulted in MIE isotope separation processes that are about 10 to 30 times more effective and efficient than KIE based processes. This recent development is presently limited to laboratory tests of hydrogen purification from deuterium and tritium requiring the use of substantially contiguous graphene membranes, and have therefore found no commercial solution, partly because such films are still not commercially available, and also because that kind of process is very slow in the flux transfer rate of hydrogen gas, which first dissolves through the graphene to enable this kind of separation to take place. Another method allowing much greater flow per cross sectional area may be chosen to enable commercial hydrogen isotope separation.

The principle of nuclear magnetic resonance (NMR) also depends on the MIE. It usually involves two sequential steps. First, a constant magnetic field is applied to align or polarize the magnetic nuclear spins into a selected direction. Then, this alignment of nuclear spins is disturbed by applying an electro-magnetic radio frequency (RF) pulse, which is then removed. A RF detector then receives the characteristic nuclear ringing echo frequencies, which couples with the electrons in those isotopes expressing the MIE, to generate radio waves. This ringing effect lasts for a few minutes. The target perturbing frequency depends on the strength of the static magnetic field. Isotopes that do not have a nuclear magnetic moment generate no echo among their electrons and are invisible to this ringing effect.

The MIE effect is not expressed by hydrogen atoms. However, coupling is achieved between the deuterium nucleus and its electron. This coupling is even greater in magnitude between tritium and its electron. When each of these isotopes are stripped of their electron, then the amount of MIE effect provides a greater interaction of nuclear magnetic moment with some isotopes and any electrons that may be in the vicinity, thereby causing a differential resistance to the passage of the isotope positive charge as it interacts with negative charges that are also transported to flow in medium that is conductive to both protons and electrons.

Nuclear polarization only lasts a few minutes. The present MIE isotope hydrogen separation technology is therefore focused on the improvement of practical solutions to perform the separation before the polarization effects have decayed beyond the point of usefulness. This can be achieved by passing the isotopes through a very thin layer where they are only activated while passing within this thin layer for a short period of time. Unfortunately, this filter effect is slow, as few isotopes are able to cross the area of the filter. The passage of atoms per area of filter is termed the flux. It is desirable to increase the effective surface area of the filter, since the flux is not sufficiently enhanced by increasing the electronic current density in the filter in those devices presently used to perform this type of hydrogen isotope separation operation.

Proton conductivity can be thought of as free radical transport of hydrogen free radicals having a positive charge. Another term used to describe hydrogen free radicals is protium, to distinguish it from deuterium and tritium having one and two neutrons added to the proton, respectively.

Protium-conductive lamina, such as graphene, is not substantially permeable to other isotopes of hydrogen, because only the proton is small enough to pass between the atoms in a contiguous sheet of nanometer scale thickness having no other pores or passages. Isotope filtering by the conduction method is substantially limited to hydrogen. Graphene is resistant to deuterium isotope conduction, and even more resistant to tritium isotope conduction. This differential resistance acts as a filter to preferentially conduct protons, and to retard and to concentrate deuterium and tritium allowing the purification of hydrogen free radicals or protium. This technology may have economic importance in cleaning waste isotopes from nuclear reactors that can damage life. At present, the focus is on graphene as the material with suitable properties and with the least cost to manufacture this type of isotope separation device.

Developing large webs of contiguous conductive graphene to permit the implementation of significant surface areas having excellent electronic and protonic conductivity has only recently been achieved. It is desirable to develop a material having uniform and excellent percolation of electrons and protium to enable hyperpolarization effects to be distributed over large areas and on atomic scales with substantially no gaps in the conductive substrate. Then, as electron current densities and DC voltage increase across the plane of the graphene film, protium conduction occurs, in which hydrogen free radicals (protium) pass most freely through the film in a direction normal to the plane of that film, whereas tritium or deuterium are hindered from passing. This process is termed electrochemical pumping.

Incremental progress in electrochemical pumping technology has been achieved by decorating graphene of monoatomic (nanometer scale) thickness, with deposited platinum metal atoms thereon to increase overall electrical conductivity. Also, by wiring across cracks, crevices, and discontinuities in distinct graphene lamina of limited planar area can be effected using conductive carbon fibers, nano-rods, or the use of similar electrical bridging techniques, capable of providing good charge carrying ability. These assemblies are often termed “webs.” Webs encompass graphene that can be mounted, chemically bonded, or grown by chemical vapor deposition (CVD) into substrates capable of supporting these fragile atomic scale structures. Even so, these structures can pass hydrogen gas.

Another rapidly developing technological, area of isotope separation involves silicon. In about 1998, it was first proposed that future very large scale quantum mechanical computation devices can require selective construction of silicon devices having an isotope optimized for non-nuclear-magnetic interaction to reduce atomic reactions to RF noise. Quantum mechanical-based silicon logic device technologies can then take full advantage of an electromagnetically “quiet” substrate for localized spin manipulation of desirable dopant atoms having a very large nuclear magnetic interaction with electrons at targeted locations in these device structures.

Use of the nuclear magnetic resonance (NMR) polarization signals of dopant atoms such as isotope 31-Phosphorus (31-P), placed into non-nuclear magnetic silicon, allows quantum mechanical logic operations that are expressed using states of 1, 0, and “maybe” values of dopant atomic spin by conserving information within their strong nuclear magnetic moment, using precession that interacts with the atomic electrons of these dopant atoms. This device logic requires the removal of 29-Silicon (29-Si) atoms, which can be hyperpolarized by RF radiation that creates noise, to destroy the injected spin signal intended to operate on desirable dopant nuclear magnetic resonant atoms of chemical nature different from silicon.

Relative to silicon quantum logic gates, very expensive processing by KIE has been used to make demonstration devices from little more than a few grams of such materials to explore their function and allow incremental design advancement to take place. The use of mass differences between chemically identical silicon isotopes by application of energy intensive cooling, heating, or centrifugal techniques, broadly classified as KIE, were not commercially supplanted by silicon separation techniques that took advantage of MIE. MIE separation theory has been available but was rarely practiced for silicon, because attempts to scale up liquid micellar solutions for free radical-based separation still have extremely poor control of the degrees of freedom required to effect a rapid and cost-effective based silicon purification. Modern multidisciplinary efforts still focus on the old KIE ideals, and many practitioners are poorly equipped to bridge wide bodies of knowledge with a sufficiently deep understanding of nuclear magnetic physics, photochemical chemical forces, and the nature of entropic forces between unlike phases.

The other known MIE application to isotope separation has used the confinement of atomic isotopes having a high atomic mass to solvent “cages” called micelles, which are liquid drops that form a barrier with a second liquid that has limited miscibility or solubility with the first liquid. Liquids are good conductors of ions, therefore it was thought that some form of oriented liquid could be used to distinguish MIE by favoring a chemical reaction rate enhancement. In practical application, such methods are ineffective or less effective than KIE at producing isotope separations based on differential chemical reactivity. Glassy ionomers have an inability to remain sufficiently rigid to assure the constrained geometry required for spin-based chemical separations. It is a desirable objective for a MIE nucleus to express a substantially different reaction time or pathway with respect to the triplet and the singlet excited states to allow adequate geometry-dependent immobilization to provide magnetic isotope separation from non-magnetic isotopes. Spin separation is difficult to achieve using micelles, or caged solvents, for similar reasons: the number of degrees of freedom is not substantially different for MIE isotopes at the interfacial wall of solvent micelles, or in any liquid based medium, even if these are liquid crystalline in nature. This limitation arises because the polarized orientation of the excited MIE isotope may not be sufficiently maintained even in a strong magnetic field, and moves randomly into other configurations that are insufficiently constrained during chemical reaction to allow cost effective and rapid separation. However, such a separation can utilize the unlike chemical reaction products of differing isotopes, or the unlike partitioning of differently reacting isotopes.

Deuterium (2-H) and tritium (3-H) are isotopes that may foul a substantial amount of water, especially reactor-irradiated water. Tritium has leaked from 75% of nuclear sites in the US. In many cases, reactor-irradiated water has contaminated ground water supplies. http://www.matcor.com/75-percent-of-us-nuclear-sites-have-corrosion-issues-leaking-tritium/. These concentrated, lethal isotopes are readily incorporated into the human body when contaminated water is ingested, where they deliver deadly radiation. In addition, deuterium and tritium-laced water can cause cell division problems and sterility, and, in sufficient concentrations, death by cytotoxic syndrome (bone marrow failure and gastrointestinal lining failure). Indeed, in connection with the Fukushima Da-ichi Nuclear Power Plant (FDNPP) disaster in March 2011, the Japanese government announced, in 2013, that there was no “drastic” technology available to remove tritium from water. http://irid.or.jp/cw/wp-content/uploads/2013/11/RFI_Result1118_1_21.pdf. Thus, a need exists to separate tritium (3-H) and deuterium (2-H) from the desired protium (1-H) in water. In addition, vast amounts of radiocesium (137-Cs) has been found in groundwater beneath sand beaches over tens of kilometers from the FDNPP, and remediation of this radioactive environmental contaminant is needed.

What is needed is a method and an apparatus for effectively managing the concentration of all types of nuclear magnetic isotopes. More economical isotope purification would allow their widespread use, saving lives and benefiting society. Also, an energy efficient purification for silicon isotopes would be useful to address the commercial production requirement of large scale electronic applications in quantum computational devices to reduce the energy required, and to minimize the time needed, to perform cost-effective isotope purification of silicon.

Additionally, no practical effort is being placed on non-conductive nanometer scale solid substrates as isotope separators, because such materials have not demonstrated a known ability to perform isotope separation by elevating some isotope conductivity with respect to other isotopes. This is because insulating materials, by themselves, do not express a differential conductive energy barrier that is known to be capable of concentrating isotopes by their faster or slower conductive permeation. Such a view seems both defined as well as limited by the definition of insulating solids as non-conductors of moving charges.

A more generalized method using nanomaterials, both conductive and non-conductive, is needed to permit isotope concentration and more energy efficient separation for a broad range of chemically distinct substances having very different therapeutic uses and industrial applications including, without limitation, nuclear reactor safety, quantum logic devices, brain machine interfaces, and cancer therapies, using insightful application of scientific principles to reduce the energy required and to minimize the time needed to perform isotope separations.

### SUMMARY OF THE INVENTION

Apparatus and method embodiments are provided. Embodiments of a metamaterial apparatus include a nanomechanical magnetoelectric (ME) element having an insulator; a conductive graphene sheet suspended as a heterostructure onto the insulator, where the conductive graphene structure has atomic-scale thickness; and a gallery between the insulator and the conductive graphene sheet. The nanomechanical ME element comprises atomic forcipes. In some embodiments, the atomic forcipes are acoustically-actuated, and where acoustic actuation further includes sonic waves provided to the atomic forcipes to stimulate magnetization oscillations in the graphene sheet of the atomic forcipes, where the sonic waves have a frequency of between about 20 Hz to about 2.0 GHz, and where the magnetization oscillations result in the radiation of electromagnetic waves. In other apparatus embodiments, the atomic forcipes are electromagnetically actuated, where the electromagnetic actuation further includes electromagnetic waves provided to the atomic forcipes to stimulate electromagnetic oscillations in the graphene sheet of the atomic forcipes, where the electromagnetic waves have a frequency of between about 2 Hz to about 500 THz. In some embodiments, the sonic waves further comprise bulk acoustic waves, where the ME element is a ME antenna, and where the bulk acoustic waves stimulate magnetization oscillations of the graphene sheet resulting in the radiation of electromagnetic waves from the ME antenna.

In some embodiments, the insulator comprises a fractional topological insulator. The fractional topological insulator includes a piezoelectric material. Some embodiments of a piezoelectric material are a montmorillonite outer negative expressed surface charge clay sheet composition. Others are a magnesium hydroxide positive expressed surface charge clay sheet composition. The clay sheet composition includes a thin film of charged, optically transparent smectite clay. In other embodiments, the insulator includes a piezoelectric material being a topological insulator having a nanometer-scale solid transition element oxide crystalline particle, where metal oxide impurities in the particle express a stratified internal charge opposite to a charge expressed on a particle surface, and express the photo-activity of surface charge separation, where electrons and holes become mobile and separable in space after irradiation by light, where movement of both types of charges express a preferred orientation in their quantum spin state, and where the preferred orientation is up or down. In embodiments, the light includes an ultraviolet (UV) light. In some embodiments, the graphene sheet expresses either polarization when a magnetic field is applied, or magnetization when an electric field is applied, the polarization provided by charge carriers including positively charged dissolved protons and negatively charged mobile electrons, and has electrons and holes with a preselected quantum spin orientation during surface charge migration, where opposing charges migrate substantially into opposing longitudinal planar graphene sheet directions. In certain embodiments, the piezoelectric material has a transparency of greater than about 95%, has a topological insulating dielectric property, has a stratified internal charge distribution that is opposite to an expressed external surface charge, and has a photolysis-assisting chemical property.

In other embodiments, the conductive graphene sheet is provided with a proximal longitudinally abutting presence of at least one electrically charged lamina in a confined layer, and the conductive graphene sheet is provided with oscillating electromagnetic activation to produce oscillating structural changes in aspect ratio of the conductive graphene sheet creating an electromechanical loss, and where the primarily mechanical component of the electromechanical loss is converted to phonons. In still other embodiments, the conductive graphene sheet is provided with a proximal longitudinally abutting presence of at least one electrically charged lamina in a confined layer, and the conductive graphene sheet is provided with oscillating acoustic activation to produce oscillating physical displacement changes having a primarily dielectric energy loss, where the primarily dielectric energy loss results in emanated electromagnetic waves. In yet other embodiments, the conductive graphene sheet is provided with a proximal presence of ionic nuclear magnetic isotopes in a confined geometry between surfaces of abutting sheets, and the conductive graphene sheet expressing a magnetoelectric effect is provided with oscillating electromagnetic activation or oscillating acoustic activation to produce ferroelectric coupling hysteresis, wherein ferroelectric coupling hysteresis results in an energy conversion of nuclear magnetic loss by anisotropic spin-orbit coupling, where a chemical potential of directionally enhanced chemical reaction rate is generated. In even other embodiments, the bulk acoustic waves applied to the atomic forcipes stimulate magnetization oscillations of the graphene sheet, resulting in the radiation of electromagnetic waves from the atomic forcipes.

In embodiments in which the piezoelectric material has a static electric field, where electromagnetic fields of received electromagnetic waves induce an oscillating electric field in the graphene sheet, and provide an induced electric voltage across a substantially in-plane longitudinal aspect of the graphene sheet, where the induced electric field oscillations react against the static electric field, causing mutually attractive and mutually repulsive mechanical forces to arise between abutting parts of the atomic forcipes, and wherein the induced electric field oscillations create phonons in proportion to the induced oscillating electric field. In some embodiments in which the atomic forcipes are acoustically-actuated, the atomic forcipes includes a functional surface group having a Lewis acid or a Lewis base, the functional surface group being disposed on surfaces of the atomic forcipes, the functional surface group composed to form free radicals under UV light irradiation, where the functional surface group forms a substantially stable hydrogen bond adduct with a free-radical-containing species, where the free-radical-containing species includes a mixture of ionic isotopes of identical atomic number but differing atomic masses, where the mixture of ionic species has at least one of the mixture of ionic isotopes expressing the magnetic isotope effect (MIE) by nuclear magnetic resonance in an electromagnetic field, and where the free-radical-containing species are geometrically constrained by at least one physical solid steric barrier of the atomic forcipes, and constrained by interaction with a local intrinsic electric field present at the electrically insulating piezoelectric component of the atomic forcipes together with the local induced electric field of the electrically conductive component of the conductive abutting graphene sheet of the atomic forcipes. The free-radical-containing species includes a solvated liquid; a gaseous vapor; an atomic cation; an atomic anion; a molecule having positive charge (cation); a molecule having negative charge (anion); a free radical; a Lewis-base capable of reacting with a free radical; or a Lewis-acid capable of reacting with a free radical.

A method for synthesizing a metamaterial apparatus can include providing enhanced graphene; selecting layered enhanced graphene having a preselected particle size; providing layered piezoelectric material sheets of smectite clay; separating layered sheets of piezoelectric material into exfoliated piezoelectric material particles; selecting piezoelectric material particles having the preselected particle size; combining enhanced graphene particles with piezoelectric material particles into a mixture; and adding a compatibilizer to the mixture, so that atomic forcipes are formed. In some embodiments, the atomic forcipes synthesizing method can further include, after combining graphene particles with piezoelectric material particles into a mixture, irradiating the mixture with ultrasound. In other embodiments, the atomic forcipes synthesizing method can further include, after combining graphene particles with piezoelectric material particles into a mixture, irradiating the mixture with UV light. In still other embodiments, the atomic forcipes synthesizing method can further include, after combining graphene particles with piezoelectric material particles into a mixture, irradiating the mixture with microwaves. In selected embodiments adding a compatibilizer further includes adding an intercalant ion into the mixture; or adding bee honey into the mixture. In embodiments, the method further includes providing additional irradiation to the atomic forcipes. In some embodiments, providing additional irradiation further includes one or more of providing microwave irradiation; providing Terahertz radiofrequency irradiation; providing ultraviolet irradiation; or adding hydrogen peroxide to the atomic forcipes and providing microwave irradiation. Certain method embodiments further include adding a preselected intercalant solution to the atomic forcipes. In embodiments, selecting the graphene particle size further includes selecting a graphene particle having the particle size of between about 20 nanometers to about 2 microns. In embodiments, separating layered sheets of piezoelectric material into piezoelectric material particles, further includes using Woltornist interface trapping and exfoliating process to obtain piezoelectric material particles; and irradiating piezoelectric material particles with ultrasound for about 1 hour to obtain smectite clay sheet particles having a layer of about 1 nanometer thickness. In embodiments, providing graphene particles further includes using the Woltornist interface trapping and exfoliating process to obtain exfoliated graphene sheets having a single atomic thickness of about 1 nanometer.

In some embodiments of a method for synthesizing a metamaterial apparatus, adding an intercalant ion into the mixture further includes adding an intercalant ion solution having about 10% nuclear magnetic isotope intercalant. In selected embodiments, the nuclear magnetic isotope intercalant includes deuterium oxide.

When adding bee honey into the mixture, embodiments further include adding up to about 1% of bee honey to the mixture. In embodiments, providing microwave irradiation includes placing the mixture into a microwave oven at about 100 watts for about less than one minute; or providing Terahertz radiofrequency irradiation at about 400 watts for less than about 10 minutes; or providing modulated optical irradiation from infrared wavelengths to visible wavelengths. In embodiments, adding a preselected intercalant ion further includes providing robustly surface bonded nuclear magnetic isotope intercalant to the atomic forcipes.

Embodiments of an isotope separator include a low pressure oven chamber, reflective of radio waves; atomic forcipes disposed in powder form within the oven chamber, the atomic forcipes including a piezoelectric sheet and a graphene sheet, with a gallery region therebetween; isotope vapors within the oven chamber to react with the atomic forcipes, where the isotope vapors enter the oven chamber heated and vaporized, where there is a first isotope and a second isotope in the isotope vapor, wherein the isotopes react with the atomic forcipes to create a forcipes-isotope mixture; an UV lamp disposed within the oven chamber and provided to irradiate the forcipes-isotope mixture; an ultrasonic activator disposed within the oven chamber and provided to ultrasonicate the forcipes-isotope mixture; and a programmable magnetron disposed within the oven chamber and provided to irradiate the forcipes-isotope mixture, where the second isotope is bound as an adduct to at least one sheet of the atomic forcipes, and where the first isotope is released from the atomic forcipes. Certain embodiments of the isotope separator apparatus further include a carrier gas introduced into the oven chamber to circulate the isotope vapors. In other isotope separator embodiments, the isotope vapors include water vapors having a protium isotope, and a deuterium isotope or a tritium isotope or both, where the second isotope is a deuterium isotope or tritium isotope, where hydrogen-bonded adducts of the deuterium isotope or the tritium isotope or both are retained in a gallery region of atomic forcipes, and where the protium isotope reversibly dissolves into and out of the graphene sheet. In still other isotope separator embodiments, the second isotope is 29-Si, and the first isotope includes 28-Si or 30-Si or both. In yet other separator embodiments, the second isotope is a semiconductor dopant for ion beam implantation into silicon in a quantum mechanical logic circuit or a quantum mechanical logic device.

Another apparatus embodiment of an isotope separator includes a levitated suspension of atomic forcipes; a gaseous vapor stream in contact with and levitating the atomic forcipes, wherein the gaseous vapor stream includes a first isotope and second isotope; a programmable electromagnetic transducer providing actuation to the atomic forcipes by electromagnetic irradiation at a preselected frequency; and at least one programmable ultrasonic transducer providing actuation to the atomic forcipes by ultrasonic irradiation between about 20 Hz to about 20 GHz, where the second isotope is bound as an adduct to a solid surface of the atomic forcipes, and where the first isotope is released from the atomic forcipes and is entrained in a purified gaseous vapor stream. In embodiments of the isotope separator apparatus, where the gaseous vapor stream is steam, the preselected frequency is between about 2.4 GHz and about 2.6 GHz, the second isotope is deuterium and tritium, and the first isotope is protium. In other embodiments of the isotope separator apparatus, where the gaseous vapor stream is one of silane (SiH4) or silicon-halogen (SiX) vapor, the second isotope is 29-Si, and the first isotope includes 28-Si and 30-Si.

Method embodiments for isotope separation include providing a levitated suspension of atomic forcipes; providing a gaseous vapor stream in contact with and levitating the atomic forcipes, wherein the gaseous vapor stream includes a second isotope and a first isotope; providing kinetic activation and free radical initiation an intercalated species within the gallery of the atomic forcipes by electromagnetic irradiation at a preselected frequency; providing actuation to the atomic forcipes by ultrasonic irradiation between about 20 Hz to about 20 GHz; binding the second isotope as an adduct to at least one sheet of the atomic forcipes; releasing the first isotope from the atomic forcipes; and entraining the first isotope in a purified gaseous vapor stream. In embodiments where the gaseous vapor stream is steam, the preselected frequency is between about 2.4 GHz and about 2.6 GHz, the second isotope is deuterium or tritium or both, and the first isotope is protium. This may be useful to clean pumped water from FDNPP. In other embodiments where the gaseous vapor stream is one of silane (SiH4) or silicon-halogen (SiX), the second isotope is 29-Si, and the first isotope includes 28-Si or 30-Si or both.

Another method embodiment for isotope separation, includes providing a piezoelectric nanoparticle sheet; irradiating the piezoelectric nanoparticle sheet with ultraviolet light; generating surface free radicals on the piezoelectric nanoparticle sheet; providing a conductive graphene sheet; polarizing the conductive graphene sheet to make a polarized conductive graphene sheet; mixing the piezoelectric nanoparticle sheet with surface free radicals with the polarized conductive graphene sheet to create unlike nanoparticle suspension; applying ultrasonic energy to unlike nanoparticle suspension; intercalating the piezoelectric nanoparticle sheet with surface free radicals with polarized conductive graphene sheets in the suspension; forming atomic forcipes; creating an aqueous phase suspension with atomic forcipes; mixing the aqueous phase suspension with nuclear magnetic isotope ions; applying ultrasound to the suspension to promote nuclear magnetic isotope ion intercalation; applying ultraviolet light to the suspension to generate free radicals on the isotope ions; and extracting enriched isotope ions from the piezoelectric nanoparticle sheet in the suspension. In embodiments, the method also includes providing ultraviolet light to the piezoelectric nanoparticle sheet generating surface free radicals. The piezoelectric nanoparticle sheet includes a montmorillonite type of piezoelectric clay nanoparticle sheet. The method embodiments further can include, before extracting the enriched nuclear magnetic isotope ions, irradiating the suspension with microwaves to enhance the reactivity of the nuclear magnetic isotope ions with the atomic forcipes. Selected method embodiments can include, before extracting the enriched nuclear magnetic isotope ions, removing the non-nuclear magnetic isotopes.

Still another method embodiment for isotope separation includes providing piezoelectric clay sheets; implanting atoms having Lewis-type free electron pairs into the piezoelectric clay sheets; providing a graphene sheet; enhancing the graphene sheet to form an enhanced graphene sheet having near-field quantum enhancement; intercalating the enhanced graphene sheet between piezoelectric clay sheets having free electron pairs, wherein atomic forcipes are formed; introducing an isotope mixture having a second isotope and a first isotope to the atomic forcipes, creating a isotope-forcipes mixture; applying one of UV light, phonon sound, or RF energy to isotope-forcipes mixture; and extracting concentrated reacted nuclear magnetic isotope from the isotope mixture, the concentrated reacted nuclear magnetic isotope being one of the first isotope or the second isotope. Implanting atoms having Lewis-type free electron pairs into the piezoelectric clay sheets further includes one of implanting nuclear magnetic isotope dopant atoms with free electron pairs into the piezoelectric clay sheets; or ion-exchanging organic onium with free electron pairs into piezoelectric clay sheets. In embodiments, enhancing graphene sheets further includes one of immersing graphene sheets in a short-chain amine-containing solvent, wherein the short-chain amine-containing solvent allows a covalent bond with cations of nuclear magnetic isotopes by forming a geometrically-constrained nitrogen adducts; or oxidizing the graphene sheets to form graphene oxide and partially reducing the graphene oxide to form reduced graphene oxide in the presence of a microwave field to leave carboxylic acid functional groups having Lewis base electron pairs, the electron pairs forming adducts with nuclear magnetic isotopes under ultrasonic activation proximate to the piezoelectric clay sheets.

Yet another embodiment for an isotope separation method includes separating a magnetic isotope effects isotope from a non-magnetic isotope effects isotope based on nuclear spin using nuclear magnetic stiction.

Still other nanomechanical magneto-electric element embodiments, which have atomic forcipes, can include piezoelectric clay sheets, wherein the piezoelectric clay sheets have surface atoms expressing free electron pairs; an enhanced conductive graphene sheet intercalated between the piezoelectric clay sheets, wherein the enhanced conductive graphene sheet has a near-field quantum enhancement; and a respective gallery between each of the piezoelectric clay sheets and the enhanced conductive graphene sheet, wherein the respective gallery includes a guest atomic intercalant ions. The atomic forcipes can be one of a transmitting antenna or a receiving antenna, a sensor or an actuator, or an electromechanical pump or an electrochemical pump. The atomic forcipes has a capacitance (C) from the clay, an inductance (L) from the graphene, and a reactance (R) contributed by guest atomic intercalant atoms having capacitive reactance and inductive reactance. The reactance is coupled to the capacitance and the inductance, in which a resulting LCR circuit provides dynamic oscillation frequencies. The nanomechanical magneto-electric includes dopant implanted into external surfaces of the piezoelectric clay sheets. In selected embodiments, the atomic forcipes further include piezoelectric montmorillonite insulator sheets; atom-thick graphene sheets, in which each of the graphene sheets is intercalated with respective piezoelectric montmorillonite insulator sheets; and galleries with each gallery is between a respective graphene sheet and a corresponding piezoelectric montmorillonite insulator sheet. Atomic forcipes can include a solar radiation management apparatus using piezoelectric montmorillonite insulator sheets and atom-thick graphene sheets matched in diameter and tuned to interact with the light or radio frequency wavelengths of the irradiation chosen for energy input and angular momentum near-field effect particle levitation control output. In embodiments the atomic forcipes can also include a nuclear magnetic isotope (NMI) disposed in a gallery, the NMI extracted from an isotope mixture, wherein NMI atomic forcipes is formed. The NMI atomic forcipes can include a sensor, a transceiver, a transceiver in an Internet of Things device, or a RFID tag transceiver. In certain selected embodiments of a NMI transceiver, the atomic forcipes are disposed in a biological entity and the transceiver is configured to communicate with a computational device external to the biological entity.

These and other advantages of the embodiments will be further understood and appreciated by those skilled in the art by reference to the following written specifications, claims and appended drawings.

### BRIEF DESCRIPTION OF THE DRAWINGS

Embodiments of the invention will now be described, by way of example, with reference to the accompanying drawings, in which:

FIG. 1 illustrates an edge-on view of atomic forcipes, showing cationic intercalants between a graphene sheet and smectite clay, in accordance with the teachings of the present invention;

FIG. 2 illustrates an edge-on view of atomic forcipes, showing free radical initiation on light irradiation of graphene and smectite clay sheets, in accordance with the teachings of the present invention;

FIG. 3 illustrates an edge-on view of atomic forcipes, showing ultrasonic irradiation applied during light irradiation of graphene and smectite clay sheets, in accordance with the teachings of the present invention;

FIG. 4 illustrates an edge-on view of atomic forcipes, showing adduct formation during ultrasonic and UV treatment between graphene and smectite clay sheets, in accordance with the teachings of the present invention;

FIG. 5 illustrates an edge-on view of atomic forcipes, showing adduct stability maintained between graphene and smectite clay sheets after removal of ultrasound, in accordance with the teachings of the present invention;

FIG. 6 illustrates an edge-on view of atomic forcipes, showing microwave assisted biased polarization and displacement of a graphene sheet between canted smectite sheets, in accordance with the teachings of the present invention;

FIG. 7 illustrates an edge-on view of atomic forcipes, showing microwave assisted alternative polarization and displacement of a graphene sheet between differently canted smectite sheets, in accordance with the teachings of the present invention;

FIG. 8 illustrates an edge-on view of atomic forcipes, showing cationic intercalants between a graphene nanometer sheet and phosphorus doped smectite clay, in accordance with the teachings of the present invention;

FIG. 9 illustrates the role of dissolved hydrogen in graphene, and two alternative cation types for intercalation between sheets of doped or natural smectite clay, in accordance with the teachings of the present invention;

FIG. 10 illustrates an edge-on view of atomic forcipes, showing organic cations after intercalation between sheets of doped or natural smectite clay sheets interposed between a graphene sheet, in accordance with the teachings of the present invention;

FIG. 11 illustrates an edge-on view of atomic forcipes UV-initiated unpaired electron free radical formation among intercalated organic cations, in accordance with the teachings of the present invention;

FIG. 12 illustrates an edge-on view of atomic forcipes RF polarization induced isotope pumping and nuclear magnetic isotope adduct formation among intercalated organic cations, in accordance with the teachings of the present invention;

FIG. 13 illustrates a process for making atomic forcipes, in accordance with the teachings of the present invention;

FIG. 14 illustrates a UV lamp made with a circular printed circuit board having surface mounted LEDs, in accordance with the teachings of the present invention;

FIG. 15 illustrates an edge-on view of six UV-LED lamps mounted to a speed controlled rotating shaft, in accordance with the teachings of the present invention;

FIG. 16 illustrates a solvent bath containing a powder of atomic forcipes being irradiated among a solution of heated isotopes in a reaction oven, in accordance with the teachings of the present invention;

FIG. 17 illustrates a fluidized bed bath containing a slurry or suspension of atomic forcipes to separate heavy water containing deuterium and tritium atomic waste from hydrogen water, in one type of radioactive “fallout” remediation, when used in accordance with the teachings of the present invention;

FIG. 18 illustrates a low pressure or vacuum oven chamber provided with atomic forcipes powder being irradiated and ultrasonicated above a source of heated and vaporized isotopes, in accordance with the teachings of the present invention;

FIG. 19 illustrates an edge-on view of graphene out of plane flexural stabilization by spin of nuclear magnetic isotopes, in accordance with the teachings of the present invention;

FIG. 20 illustrates a process diagram to summarize the nuclear magnetic isotope separation in accordance with the teachings of the present invention; and

FIG. 21 illustrates a process diagram to summarize an embodiment of a passive ion exchange process, in accordance with the teachings of the present invention.

The following detailed description, taken in conjunction with the accompanying drawings, is merely exemplary in nature and is not intended to limit the described embodiments or the application and uses of the described embodiments. Any implementation described herein as “exemplary” or “illustrative” is not necessarily to be construed as preferred or advantageous over other implementations.

### DETAILED DESCRIPTION OF THE INVENTION

The present embodiments provide apparatus and methods for effectively managing the concentration of all types of nuclear magnetic isotopes. Management of selected nuclear magnetic isotopes can be used to separate, for example and without limitation, tritium and deuterium from hydrogen. Management of selected nuclear magnetic isotopes can be useful for medical imaging, and for molecular synthesis of nuclear-magnetic drugs which may be used, for example, in regulating heart tissue energy supply for stroke mitigation. Management of selected nuclear magnetic isotopes also can supply those isotopes used in a range of diverse drug therapies, including cancer cell antibodies. Barriers to the application of nuclear-magnetic drugs includes the cost of isotope purification and the energy-intensive purification processes, which barriers have been presently surmounted.

The overarching improvement in magnetic separation of isotopes is the development of a new type of isotope separation, using both the nucleus and the electron of the nuclear magnetic atom to create a hydrogen bond in two abutting free radicals. Here, the nuclear magnetic isotope ion in a first free radical obtains a “0” state spin when the spin of the electron is down and the nucleus spin is up, while the “1” state is when the electron spin is up, and the nuclear spin is down.

The present embodiments provide atomic forcipes apparatus and methods employing atomic forcipes. Hereinafter, the term “atomic forcipes” can represent a sinle entity or plural entities. The atomic forcipes apparatus can be a type of nanomechanical electromagnetic system (NEMS) operated to oscillate ionically and electronically conductive laminae activated by phonons and electromagnetic RF irradiation to provide a geometric free radical solid interfacial bonding clamp and isotope separator. Phonons can be by sonic or ultrasonic waves. Also included are isotope separators and methods for separation of nuclear magnetic isotopes from bulk isotope mixtures.

Because atomic forcipes can be, in general, a combination of at least two nanometer-scale materials having unique functionality different from either composition alone, atomic forcipes can be a metamaterial apparatus. Atomic forcipes also can be nanomechanical magneto-electric (ME) antennas, with a suspended atomic-scale thickness of conductive graphene structure layered as a heterostructure onto an insulator, which may be a topological insulator. Graphene is a non-piezoelectric allotrope of carbon, typically in the form of a two-dimensional, atomic-scale, hexagonal lattice in which one atom forms each vertex. Atomic forcipes can be acoustically actuated, electromagnetically actuated, or both. The insulator can be a fractional topological insulator with fractional topological phases. In some embodiments, the insulator can be a piezoelectric material. The piezoelectric material can be a thin film of charged optically transparent smectite clay. The clay can be one contiguous sheet thickness of hydrated (Na+1, or Ca+2), intercalated, negatively charged aluminum magnesium silicate hydroxide, having piezoelectric properties similar to that of quartz, and being able to bind with positive charged or cationic free radicals. Therefore, a montmorillonite outer negative expressed surface charge clay sheet composition, or a magnesium hydroxide positive expressed surface charge clay sheet composition, can be suitable for the insulator in these embodiments.

Atomic forcipes metamaterial can couple at least one incipient topological conductor, which may be a graphene sheet of atomic layer thickness, to at least one incipient topological insulator, such as a clay sheet expressing a net negative surface charge and having paramagnetic properties. The incipient topological phase transition is that point where a critical concentration of dissolved protons in graphene provides stabilization of the fractional topological phase by at least one mechanism, such as, without limitation, by Kane-Mele-Hubbard third neighbor hopping. See Hung, et al., “Topological phase transition in a generalized Kane-Mele-Hubbard model: A combined Quantum Monte Carlo and Green's function study,” Physical Review B, 87 (12). Art. No. 121113, ISSN 1098-0121, 12 March, 2013. A critical concentration of dissolved protons in graphene provides at least one type of interaction to stabilize the topological phase. Atomic forcipes operates with intercalated ions of a nuclear magnetic isotope in the presence of protons from hydrogen, free radicals at the surface of the clay, and an energy for activation consisting of acoustic, radio frequency, or light to generate free radicals. Atomic forcipes may incorporate nuclear magnetic isotopes of any element into the metamaterial gallery region between an insulator material such as clay and a conductor such as graphene.

In other embodiments, the insulator can be a transition element oxide nanometer-scale solid crystalline particle. The particle can be of the type specifically expressing the photo-activity of charge separation wherein electrons and holes become mobile and separable in space after irradiation by light. The particle can be composed of (in decreasing order of preference): ZnO, ZnS, WS2, WSe2, MoS2, MoSe2, or TiO2 (containing the anatase crystal form). In general, the piezoelectric particle can have greater than about 95% transparency, can have piezoelectric material having a topological insulating dielectric property, can have a stratified internal charge distribution that is opposite to the expressed external surface charge, can have a preferred quantum spin orientation of expressed surface charges, and can have a photolysis-assisting chemical property. The clay can include a transition element composition with metal oxide impurities.

The conductive graphene sheet of the atomic forcipes expresses a polarization when a magnetic field is applied, or, conversely, a magnetization of that material when an electric field is applied. These properties can be enabled by charge carriers composed of positively charged dissolved protons and negatively charged mobile electrons. Typically, opposing charges migrate substantially into opposing longitudinal planar graphene sheet directions.

The conductive graphene sheet, when provided with the proximal longitudinally abutting presence of at least one electrically charged lamina in a confined layer, expresses a ferroelectric coupling hysteresis under oscillating electromagnetic activation such as by interaction with transient radio waves or transient currents. In general, this coupling results in a structural changes in aspect ratio having a mechanical loss to generate acoustic waves or phonons as a result of this energy conversion. The graphene sheet also expresses a ferroelectric coupling hysteresis under oscillating acoustic activation such as by interaction with transient phonon waves. This coupling can result in physical displacement changes having a dielectric energy loss by means of emanated electromagnetic waves or radio frequencies arising as a result of energy conversion. In addition, the conductive graphene structure, when provided with the proximal presence of ionic nuclear magnetic isotopes in a confined geometry, expresses a ferroelectric coupling hysteresis under oscillating electromagnetic or acoustic activation. The coupling can result in a nuclear magnetic loss by anisotropic spin-orbit coupling to generate a chemical potential of directionally enhanced chemical reaction rate as a result of this energy conversion.

The ratio of graphene to clay may be provided by a statistical proportion of the per sheet ratio of about ⅓ of one type by about ⅔ of the other. The goal is to ensure each abutting sheet of nanoparticle has one partner of the other type in a microscopic structure.

Nuclear magnetic isotope ions that have been excited by light irradiation or ultrasound can form singlet pairs. Self-reactions involving magnetic isotopes occur with a more rapid rate and at a higher probability than those of non-magnetic isotopes. This pair formation is especially rapid when a sufficiently strong radio frequency is applied in a strong magnetic or electric field to interact with and excite the magnetic isotopes, but not the non-nuclear-magnetic isotopes. Concentration effects that allow for later nuclear magnetic isotope separation in random natural isotope mixtures are provided using the free radical chemistries of Lewis base and Lewis acid pairs. These and similar embodiments are designed to take place to provide an escape reaction or an escape process to the nonmagnetic isotope pairs.

In chemistry, a Lewis base is any molecular or atomic species that donates an electron pair, where such an electron pair is indicated herein by the symbol “:”, as in for example the “N:” for nitrogen electron pair, or “0:” for oxygen electron pair, or “P:” for a phosphorus electron pair. A Lewis acid is any species that accepts an electron pair to form a covalent type of shared electron pair bond that is termed an “adduct.” A hydrogen atom stripped of its electron forms a positively charged proton H+ which has a vacant electron orbital to fill. Thus, when P: bonds to such an acid proton H+, it forms the adduct P—H+.

Chemical reactions that involve radical pairs to form adducts can be altered to depend on the presence of MIE in the isotope by application of a polarized orientation of nuclear spin, using an applied magnetic field, or an applied electric field, of sufficient strength to maintain that spin orientation. This process causes the geometric orientation of the free radical pairs to engage the odd electron spins of the pairs. The influence of nuclear spins is maximized when at least one of the radical pairs is confined to a geometric space that serves as a wall or a cage. The nuclear magnetic isotope can be held in place by a combination of electric or magnetic effects, together with precession. Precession effects on atoms can be imagined by analogy to being somewhat similar to the resistance of a spinning top from tipping over, or the resistance of a spinning bicycle tire from being manually twisted, where this kind of resistive force is actually defined as a moment of inertia that acts to maintain the geometrical orientation of the spinning object.

Interfaces between unlike phases of matter can form a wall that allows some degree of independent diffusional and rotational motion of the paired partners, preferentially in the plane of that interface. Liquid interfaces, while conducting free radical ions quite well, tend to perform rather poorly at geometric confinement, when both free radicals are free to move. Another method is required that allow the reactive pair to approach and recede multiple times until the correct angle and energy is achieved to allow covalent bond formation at some point in the multiplicity of reencounters of the partners. Moreover, the reaction should happen within a period of minutes after the nuclear magnetic polarization has been achieved, before it can decay. This time period can be important, because mutual polarization allows the nuclear spin to operate on the odd electron spins of the pair. Under the correct conditions, a proper alignment is attained where the proximal nuclear spin induces a crossover between the triplet to the singlet state of the nuclear free radical in an approaching pair of radicals, thereby enabling adduct formation. Isotopes that do not express MIE are far less able to form adducts induced by greater likelihood of a transition leading to a chemical bond between free radicals, because they do not express orientation dependent enhancement of triplet to singlet electronic state changes in the presence of applied electromagnetic fields. The dependence of adduct formation on nuclear spin under these conditions leads to a magnetic isotope effect on the chemistry of radical pairs, where transient attraction or metastable bond formation to at least one reactive site located on at least one solid surface of a metamaterial is herein termed “nuclear magnetic stiction,” or NMS. The NMS provides a way to separate MIE isotopes from other isotopes on the basis of nuclear spins utilizing MIE rather than nuclear masses utilizing KIE.

The role of an approaching non-conducting clay particle is to provide an electric charge having an electric field, “E,” that is oriented substantially normal to the plane of that surface. This electric charge pulls on the odd free electron of the first free radical, and drives it a little bit away from the nucleus, in a direction that is also normal to the approaching charged particle surface. This results in the creation of an electric dipole at the nuclear magnetic isotope free radical, where a coupling exists between the nuclear spin and the electronic spin. This coupling tends to align the spin states of the nucleus and the electron into a direction that maintains and stabilizes a nuclear precession-coupled atomic alignment with the electric field.

A second free-radical such as oxygen can be bonded to the surface of the piezoelectric clay sheet, and this bonded atom has lost one electron of its Lewis-pair to confer surface reactivity. The locally changing voltages in the deforming piezoelectric clay sheet tend to align the second electric dipole of the oxygen electron free radical to be in accordance with the timed oscillation of a dynamic electric field caused by the cyclic deformation of the piezoelectric substrate.

These differently induced electric dipoles can be used to initiate the geometrically constrained interaction over distances that approach one micron, or about 1,000 nanometers (nm). The second dipole is geometrically constrained by an existing bond to a solid surface, and the first dipole is geometrically constrained by precession effects arising from the nucleus of the atom having a nuclear magnetic moment. The attractive van-der-Waals dipole then couples with the nuclear magnetic-dipole interaction so that both may now take place over great distances, much further apart than previously thought possible, while preserving geometric dipole orientation with respect to at least one solid surface. Solid-solid interfaces, or more useful, liquid-solid interfaces in an electric or magnetic field, can act as much better geometric constraints on degrees of atomic-oriented freedom for polarized isotopes expressing MIE than the previously imagined liquid-liquid interfaces.

Oscillations in the atomic forcipes caused by phonons allow the consistent recurrent movement of geometrically confined free-radical reactants to approach each other into a proximal distance for reproducible orientation during frequent recurrent encounters over the short time period required before dipole-dipole polarization is allowed to decay. This dynamic displacement allows the reactive free radical pair to approach and recede multiple times until the correct physical position in space is achieved, and the correct magnetic field strength is present while the resonant frequency of the nuclear magnetic isotope is achieved, to allow favorable conditions for covalent bond formation at one point in the multiplicity of reencounters of these free radical reactants. During one of these encounters, the nuclear magnetic isotope triplet energy state has decayed into a singlet energy state, thereby allowing the formation of the chemical bond or adduct, and anchoring this isotope expressing MIE within the atomic forcipes.

Light of visible and UV wavelengths, as well as microwave irradiation, are known to be able to generate free radicals. A single exfoliated clay sheet, or a single graphene sheet of one atom thickness, are each significantly transparent to light of visible, UV, and microwave wavelengths. This means that free radicals can easily be formed at the interior surfaces of abutting clay and graphene sheets to generate surface-bound free radicals within their gallery region or gap. This transparency now allows the odd Lewis electron pairs of atoms that are chemically bonded to the interior surfaces of the laminae to become activated by light to generate free radicals capable of chemically interacting with mobile nuclear magnetic isotope ions.

The basic types of magnetic behavior in ions of each element may be diamagnetic, ferromagnetic, anti-ferromagnetic, and paramagnetic. A list of the type of magnetic behavior for each element is available at http://www.periodictable.com/Properties/A/MagneticType.html. Paramagnetism is magnetic attraction associated with an applied magnetic field. Oxygen and nitrogen are examples of atoms obtaining paramagnetic properties when they lose one of their unpaired electrons. Clay materials are substantially composed with oxygen, with particular expression of oxygen atoms provided with unpaired electrons at the external surfaces.

A clay sheet is not magnetic; however clay contains oxygen atoms with two unpaired electrons at its surface. Irradiation by microwaves or by UV light is able to promote one electron per oxygen atom to a sufficient energy that allows complete separation from its parent atom, leaving an oxygen free radical having one lone electron in its outer orbital. This confers a paramagnetic property to the oxygen atom. As sufficient electrons leave the oxygen atoms exposed at the surface of a clay sheet, the entire surface of the clay particle becomes paramagnetic and one part of the conditions needed for incipient topological quantum spin coupling is enabled for this insulating material. The outside surface of clay has a net negative charge because of fixed charge imbalances arising from positively charged impurities inside the clay sheet structure. Clay sheets therefore have the interesting property of being able to transform into negatively surface-charged paramagnetic particles.

Graphene is a two-dimensional quantum spin Hall conductor, which may turn into a topological conductor at low temperatures when a magnetic field is applied perpendicular to the plane of the field because of Dirac electrons present in the graphene sheet. Without a sufficiently strong magnetic field applied normal to the graphene sheet, and at room temperature, graphene is a normal conductor. When it becomes a topological conductor, electron current flows only in one direction, clockwise or counter-clockwise, around the edges of the particle, depending on the orientation of the applied magnetic field. Topological conductors have conducting surface states protected by time-reversal symmetry, wherein electron spins (or holes) are locked at right angles to their momentum or direction of travel. When the applied magnetic field varies in magnitude and reverses in direction, the graphene sheet acts as a two-dimensional inductive element in an electric circuit. This type of charge transport is different than in traditional bulk metallic conductors, where the transport of charge expresses no preferred quantum spin state orientation during the transport process. The benefit of such spin selectivity is to prevent electron backscattering from atomic scale disruptions in the motion of the electrons arising from imperfections such as folds or cracks that would ordinarily disrupt electron transport through such a thin layer of the material. These conditions usually only arise at very low temperatures and at very high magnetic fields.

The topological insulator is a solid substrate able to allow constrained charge transport only at its surface, wherein the spin-orientation of the transported electrons and holes are in alignment. Topological insulators have conducting surface states protected by time-reversal symmetry, wherein electron spins and holes are locked at right angles to their momentum or direction of travel. The quantum Hall effect normally only happens at very low temperatures close to absolute zero. Inside the material, electrons move in small circles called Lamour orbitals, but around the edges of a planar topological insulator, electrons can only move in one direction, similar to the case of the topological conductor.

Both topological insulators and topological conductors require a very high magnetic field, and extremely low temperatures to exhibit the effects of their operation, which makes either of them unsuitable for technological applications for energy and for economic reasons.

Graphene sheets of one atom thickness are likely to contain tears, cracks, and bent or folded regions. These defects have limited prior devices, but in the present embodiments, serve to enhance the function of the device by allowing gaseous or fluidic migration of isotopes into such cracks and along such folds to expedite their migration into and out of the gallery regions between adjacent pairs of laminae or parts of the atomic forcipes structure. Cracks therefore can serve to enhance the flow and diffusion of ions.

Near-field quantum enhancement may be desirable in the graphene sheet, in the clay sheet or both. “Near-field quantum enhancement” means non-linear modes of radiative energy propagation among quantum entangled charges being electrons (negative electric charge), protium (positive electric charge), the interaction of their respective quantum spin values with each other, and the interaction of their quantum states with those of atomic nuclear and atomic electron shells of nuclear magnetic isotopes that may become entangled in the gap or gallery region on the application of energy of motion so that their wave-functions, i.e., their existence as discrete entities, becomes shared with the immediate abutting solid surfaces of the unlike particles. The physical result of entanglement is a quantum operation or function composed of radiation that propagates in curved pathways as plasmons, charges that move from point to point by teleportation, and states of energy or location that are both present, not present, and partially present at the same time. The change of substance identity into an entangled or overlapping material being neither one component nor another component but a superposition of all components in the composition is what constitutes near field quantum enhancement.

The presence of defects in their pure component parts, most of which reside in the clay, is what enables the atomic forcipes to transform its identity upon the application of energy. The presence of defects can be what distinguishes atomic forcipes from other metamaterials not having sufficient defects or the correct type of defects to achieve superposition. Two defects useful for near field quantum enhancement are (1) clay surface charge expression to enable spin-coupled electron motion, and (2) an optimal distance of about 30 nm between crystal lattice stacking faults in both clay sheets and graphene sheets to generate electromagnetic confinement.

A stacking fault is the interruption of pattern or direction of ordered atomic stacking at a border that is normally associated with a crystal interface but can be associated with other types of discontinuity. Stacking faults in three dimensional crystals of uniform composition can be visible and apparent at the border between abutting crystals. Stacking faults in two dimensional smectite sheets are useful in their quantum mechanical function.

In graphene, the stacking faults can be created by ‘folds’, or by just limiting the particle diameter, or by using large contiguous sheets of graphene but covering the regions chosen for plasmonic activity with size limited hybrid particle compositions. These active regions can be greater than about 5 nanometers and less than about 40 nm in graphene. The interruption of pattern or direction of ordered atomic stacking at a crystal border or crystal interface is a stacking fault.

In clay, plasmon gap confinement is achieved by stacking faults spaced from about 25 nm to about 30 nm within the structure of the plane of the clay sheet. Plasmons may not be confined when the stacking faults are greater than about 100 nm apart in the plane of the clay sheet. Clay, being a natural material, has no regular structure of stacking faults. However, being a 2-dimensional sheet, they can be imagined as lines that may zig or zag randomly to distinguish regions of different stacking order. Artificial clay may be synthesized to express ideal stacking faults that can only be obtained in the natural random state at this time. Between stacking faults, local plasmon confinement operates. Currently, common Silicon Dioxide (SiO2) dielectric insulator may be as a common macroscopic optical and electronic substrate in abutment to graphene. Pure SiO2 material fails to express near field quantum properties because, unlike clay which is also mostly SiO2, it does not express stratified crystal lattice defects resulting in a permanent charge of the sheet to apply an electric field into abutment with graphene. The purpose of surface charges in a clay topological insulator is to magnify the Purcell Effect while keeping spin states aligned in the moving charges. Geometric confinement of the spin states can be a solution to the problem of conductive losses, such as when metals are abutted to graphene.

Other types of clay crystal defects include: the position of impurity or defect atoms at some of the repeating silicon and oxygen atoms ordered into unit cells in the crystal lattice, where these are not necessarily stratified as in clay. This constitutes a substitution of one atom of different valence (charge) than is normal for the perfect charge balance of the unit cell. Sometimes, an expected atom is missing (termed a vacancy); another defect is the presence of an unexpected extra atom (silicon or oxygen) squeezed into some location within the typical repeating pattern of the unit cell in the crystal lattice.

A planar sheet of graphene has a two dimensional surface area as compared with rods or nanotubes, thereby allowing one more degree of freedom for the polarization of the graphene sheet by the application of electronic or magnetic energy, while obtaining an out-of-plane magnetic field characteristic and an in-plane electric field characteristic. This high planar surface area increases the available electromagnetic energy coupling between it and a proximal charged piezoelectric material such as a clay lamina or a metal oxide particle immediately adjacent to it, where these coupling forces become enhanced under dynamic conditions of applied changing mechanical forces or applied changing electromagnetic forces.

A chemical mechanical pumping effect arises when alternate intercalated layers of graphene lamina and charged piezoelectric lamina produce a capacitor (C) and an inductor (L), respectively, having nanometer scaled dimensions of thickness. C can be coupled to L, creating an LC circuit. Furthermore, the capacitive and inductive contributions from guest intercalant atoms to reactance, R, lead to an LCR resonant circuit, which provides dynamic oscillation frequencies.

Conventional LCR-circuits are tuned and have fixed values of capacitance, induction, and resistance. However, in certain embodiments herein, L, C, and R can change as random ionic intercalants arrive and leave, the gap increases of decreases (or both, in flexure), or intercalant ions become displaced as the actuating energy frequency changes. If these intercalants are NMI-adducts, tuned by the rows of the resonance in their synthesis, then they are unlikely to be come easily displaced and then the LCR-circuit is more resistant to de-tuning but it is still subject to dynamic effects. Precession of the NMI provides a type of resistance or reactance (R) that is alternating in phase and delayed in time. The reactance is an inductive reactance most strongly at the resonance frequency for a preselected isotope. A carrier solvent such as hexane provides mostly capacitive reactance, also shifted in time. Some ions may be solvated and separated in heptane or hexane rather than water solutions, so that capacitive reactance may be more predominant in such cases. The negative charges in the clay lamina are fixed by their chemically bound internal impurities, however the induced charges in the graphene lamina may result in transient polarization effects resulting from an applied radio frequency, thereby creating a transient moment on the graphene sheet as well as a transient deformation in the piezoelectric material. The resultant physical displacements of the structure of the atomic forcipes constitute a pump of the atomic forcipes.

The result of RF irradiation results in a transient but strong net positive charge along a first edge of a graphene sheet, and a transient but strong simultaneous net negative charge along the opposing second edge of that same graphene sheet. That negatively charged second region of the graphene sheet can then repel the adjacent clay laminae in a direction normal to the laminae surfaces, thereby increasing the gallery gap and allowing ingress of isotope ions. Simultaneously, the first more positively charged region of the graphene sheet expresses an attractive force that narrows the gap between adjacent clay lamina in a direction normal to the laminae surfaces, thereby expelling isotope ions and any carrier gas or solvent that is forced to exit these gallery regions. Because microwaves are electromagnetic waves having both positive character and negative character that oscillate between these two extremes in a cyclic manner, the polarization of the graphene sheet can similarly oscillate in polarization, thereby initiating the reversal of the pumping direction. The electromagnetic waves can have a frequency of between about 2 Hz to about 500 THz.

The inductive reactance of the graphene sheet and the capacitive reactance of the piezoelectric material can be moderated by the concentration and chemical identity of the non-bonded ions or free-flowing solvents residing within the gap or gallery regions between the pumping atomic forcipes. Magnesium ions are differently sized than calcium ions even if they both have +2 charges, and these ions are differently charged and differently sized than hydrogen ions, or sodium ions having +1 charge, for example. These differences change the timing of the transverse approach and recession of the piezoelectric and the conductive sheets of the atomic forcipes in a viscous manner under dynamic conditions. Such changes act together to alter the in-plane longitudinal displacement of the pumping action. If the environment of the solvent or carrier gas is constant, then the presence of the ionic chemical identity and the ionic concentration provide the primary viscosity effect in altering the frequency of the dynamic mechanical oscillations of the atomic forcipes. A frequency shift, an amplitude damping, or some combination of either change are detectible as phonon wave sound propagations or electromagnetic radio waves, either of which may be used to report on the presence of ions and their concentration within the atomic forcipes. The effect can be used to report on the status of isotope separation, and when this isotope separation is constant, it can be used to report on the status of the local free-flowing ion concentration. When there is a sudden introduction of an electric field, as inside a neuronal synapse during a signaling spike, then the atomic forcipes tend to align in that electric field, producing a preferred directional component to both acoustic emissions and electromagnetic emissions that can be remotely detected and reported.

Beat frequencies may be used to further manipulate chemical reactivity in concert with geometrically oscillating confinement effects. In music, an apparent beat arises when two sound waves having nearly the same period, reinforce each other constructively and destructively. This means the intensity of sound energy perceived by the listener rises and falls in a periodic and repetitive manner. Beat frequencies arise among two waves of different wavelengths that are not some multiple of each other. In the present embodiments, the ultrasound can be selected to be on the order of tens of thousands of kilohertz to hundreds of thousands of kilohertz. Ultrasonically actuated charged particles radiate locally produced microwaves because of the magnetoelectric (ME) effect. This ME coupling with electromechanical resonance acoustic actuation is on the order of kilohertz, and is obtained substantially without a DC bias magnetic field. A multiplicity of atomic forcipes may have different sized components or differently spaced galleries to create a useful range of resonant cavities. The applied radio frequencies typically may be about 2.45 GHz irradiation, such as that found in commercial microwave ovens. Interacting radio waves may then produce respective acoustic beat frequency interactions among the range of atomic forcipes, and the strain-mediated acoustic interactions may then also produce electromagnetic beat frequency interactions in both electric and magnetic fields. Ultrasonic acoustic compression effects giving rise to local electric fields may then periodically match RF-induced electric polarization attraction of graphene laminae at periodic intervals. Interactions resulting in the development of beats arising from different modes of energy propagation may express periodic collective reinforcement, as well as periodic destructive reinforcement. This means it is not very critical to find an exact excitation frequency to allow proximal free radicals to align their odd pairs of electrons to resonate with constructive field oscillations. When proper alignment is achieved, then the chemical adduct is formed among nuclear-magnetic isotopes even if some atomic forcipes tend to have somewhat different natural resonant frequencies.

Embodiments of atomic forcipes can be directed to nuclear magnetic isotope separation and body machine interfaces, where both methods of use require induced hyperpolarization of one type of first lamina that is conductive to both protons and electrons by means of a two-dimensional solid conductor such as a graphene sheet, and a second type of material, preferentially but not necessarily, also in the form of a lamina that is substantially abutting at least one atomic scale first lamina, where this second material can be a non-conductive electrically charged piezoelectric solid capable of expressing a voltage and thereby altering the position of nearby mobile charge carriers in proportion to that voltage expressed on dynamic deformation.

For embodiments involving hydrogen isotope separation, radio frequency activation of steam at or near about 2.5 GHz is desirable to increase the diffusion rate of isotopes into and out of the atomic forcipes.

Selected embodiments support silicon isotope separation by chemical exchange reaction with, without limitation, a silane, SiH4, or a related silane, such as a halogenated silane such as SiCl4, or more generally, SiX4 where X4 represents 4 atoms of a halogen taken from the halogen family of elements including without limitation, F, Cl, Br, and I.

Embodiments herein can provide a broad diversity of novel pure isotope production uses, such as drug, enzyme, genetic tracers, anti-terror tracers, and industrial applications, such as the detection of isotope intermediates in chemical reactions, the experimental observation of protein folding as affected by atomic isotopes, or the monitoring and even the treatment of cancer in humans by nuclear magnetic isotope chemical reaction rate enhancement. Such applications may use isotopes to magnify the controlled chemical reaction rate of these drugs in nuclear magnetic treatment, for example, by accelerating the adenosine triphosphate (ATP) energy release rate and causing preferential cell death, or apoptosis, of cancer cells.

Another purpose of obtaining pure isotopes is to assist medical treatments or diagnoses. For example, the concentrated use of the nuclear magnetic resonance (NMR) polarization signals of molecules labeled with atomic isotopes allows patient imaging or “staining” of tissues that have a strong nuclear magnetic moment. NMR imaging is enabled by stable isotopes such as, without limitation, 6-Li, 13-C, 15-N, 29-Si, 25-Mg, 31-P, 43-Ca, 89-Y, and other isotopes suitable to be hyperpolarized by RF radiation and then injected into patients to increase isotope detectability. In other cases, the isotope is bonded to medical compounds, drugs, or other complex substances where the patient is then dosed and subjected to strong magnetic fields to significantly increase the local rates of chemical reactions containing such isotopes in the molecules to which they are bonded, for controllable therapies and treatments.

Embodiments also provide a hyperpolarization of discontinuous graphene sheets of one carbon atom thickness for the purpose of using this polarization to selectively insert such individual sheets between charged piezoelectric material preferentially of layered or smectite structure and having an insulating dielectric character to construct and stabilize the atomic forcipes, thereby allowing self-assembly or a robust re-assembly under the influence of at least one irradiation of ultrasound irradiation, or electromagnetic induction by RF irradiation.

Certain embodiments employ a nominal radio frequency irradiation of about 2.54 Gigahertz to cause alternating current induction and transient charge polarization of discontinuous graphene sheets of one carbon atom thickness within atomic forcipes. Another radio frequency may be used as convenient way to irradiate remote wireless atomic forcipes. This energy introduction results in coupling of graphene inductive reactance against the deforming piezoelectric material undergoing capacitive reactance to produce ultrasonic energy. During this deformation process, an electric field arises parallel to the longitudinal plane of the conductive graphene sheet, and another electric field is expressed normal to the piezoelectric sheet. The varying electric field intensity always has a proportionally associated varying magnetic field that is normal to the direction of the electric field vector in each case. The strength of the magnetic fields are dynamic or AC in nature, thereby allowing interaction with any atomic isotope with known radio frequency resonance at a specific or fixed magnetic field strength. It is generally understood that nuclear magnetic isotopes have associated radio frequency resonances where the resonance value depends on some applied non-varying direct magnetic field strength. The time-dependent or “viscous” nature of the vibrating and deforming atomic forcipes helps to assure the prevalence of a range of expressed magnetic field strengths, some of which are capable of interacting with a particular nuclear magnetic isotope that is simultaneously provided with the radio frequency used to irradiate it inside the atomic forcipes.

Other embodiments provide ultrasonic irradiation at about a nominal 40 kilohertz to cause alternating displacement of the piezoelectric material of the atomic forcipes. Other frequencies, such as, without limitation, about 20 KHz or about 80 KHz also may be used. This causes piezoelectric sheet deformation and generates a time varying voltage on the outside surface of the piezoelectric material, which then interacts with an abutting conductive graphene sheet to cause current induction and transient longitudinal charge polarization in the plane of the graphene sheet, resulting in a coupling of time varying electrical and magnetic fields, to generate radio frequency energy transmitted from the graphene sheet. The expressed radio frequency transmitted by this part of the atomic forcipes is dynamic and variable in nature, wherein a tuning operation is expressed by the changing dielectric properties of the gallery or gap region of the atomic forcipes. This tuning function is similar to the way a “balun” operates to tune an antenna in a conventional radio receiver or a conventional radio transmission device, however herein the tuning operation is expressed by changing the distance of the gallery gaps using a nanometer scaled atomic forcipes device structure. The variable frequency radio transmission periodically allows interaction with any intercalated nuclear magnetic isotope having a specific radio frequency resonance at a given environmental magnetic field existing within the atomic forcipes.

Embodiments provide optical irradiation, using, for example, an inexpensive blue or UV light source such as those conventionally used for ultraviolet curing of polymers, such as laser diodes. Such light sources can be capable of providing irradiation sufficiently capable of generating free radicals on both Lewis acid and Lewis base atoms pendant from conductive graphene laminae and non-conductive charged clay laminae, as well as those present in any reactive ions, gases, or solvent species proximal to these laminae, to allow chemical reaction between free radicals to result in the substantial adherence of nuclear magnetic isotopes to the gallery by covalent-bonds. The induced moment of inertia acquired by isotopes expressing the MIE obtains a preferred orientation that is limited by the reduced number of degrees of freedom of vectors constrained by the solid walls of the gallery, by the nuclear precession, and by the orientation of applied electromagnetic field effects, whereby the combination of these conditions ensures geometric confinement by at least one proximal solid surface and concentration of nuclear magnetic isotopes within the gallery region between adjacent laminae. These conditions eventually favor the creation of a permanent adducts or chemical bonds between pairs of free radicals magnetically held, electrostatically attracted to, and physically constrained at a gallery wall.

In one embodiment, non-conducting piezoelectric laminae are doped with phosphorus ions to create surface pendant phosphorus Lewis base electron pairs that enhance the utility of the device to form adducts with nuclear magnetic isotopes under ultrasonic activation proximal to a sheet of one atom thickness graphene.

In another embodiment, non-conducting piezoelectric laminae are ion exchanged with ammonium hydroxide or other solvent miscible molecules having amine containing nitrogen groups to create ion-exchanged surface pendant nitrogen Lewis base electron pairs that enhance the utility of the device to bond with nuclear magnetic isotopes by the formation of the geometrically constrained nitrogen adduct.

In another embodiment, the conducting graphene laminae are immersed in ammonium hydroxide or similar short chain amine containing solvents to enable the planar graphene lamina surface to be doped or decorated with pendant nitrogen Lewis base electron pairs that function to enhance the utility of this device by allowing a covalently bond with cations of nuclear magnetic isotopes by the formation of the geometrically constrained nitrogen adducts.

In another embodiment, the conducting graphene laminae of atomic forcipes are oxidized to form graphene oxide, then partially reduced in the presence of a microwave field to leave carboxylic acid functional groups that enable the reduced graphene oxide lamina surface pendant oxygen with Lewis base electron pairs to form adducts with nuclear magnetic isotopes under ultrasonic activation proximal to a sheet or particle of piezoelectric material. When graphene oxide is exposed to UV light, to microwaves or, to a lesser extent, ultrasound, it rapidly begins to lose its surface-bound oxygen and turns into reduced graphene oxide. Reduced graphene oxide is in a state somewhere between pristine graphene and pure graphene oxide, having a few residual oxides at sites of imperfections in the carbon network of graphene.

Particular embodiments can be improved in the retention of gallery gaps to enhance isotope mass transfer by the incorporation of single wall carbon nanotubes in place of some or all of the graphene sheets. Such carbon nanotubes may optionally be functionalized with carboxylic acid groups, or sulfate groups, or phosphate groups, or amine groups, or similar Lewis base species to expedite the inclusion and stable incorporation of such functionalized nanotubes into the gallery regions between adjacent clay laminae or between clay and graphene lamina, and where this construct is built and stabilized by self-assembly during the microwave and UV-induced free radical formation and adduct formation on the functionalized surfaces of the carbon nanotubes.

The single wall carbon nanotube device can be stabilized by the axial compression of the nanotube along its length as a result of a redistribution of the density of electron states by van-der-Waals polarization effects, thereby causing net positive charges to become expressed in the nanotube surfaces abutting negatively charged clay platelets.

In one embodiment. atomic forcipes also operate in a near vacuum but includes a source of low pressure vaporized gas atoms of hydrogen or silane capable of free radical initiation that are attracted to react inside the gallery region of the device during device actuation by ultrasound, photonic UV irradiation, and in some cases, optional microwave irradiation of the conductive lamina component. Silane containing atomic 31-Si is removed from bulk silane gas to concentrate non-magnetic-containing silane for the purpose of providing a nuclear-magnetic isotope free (herein NMIF) raw material finding immediate economical production demand for large scale quantum mechanical logic device structures composed with such bulk silicon. The resultant NMIF material lacks nuclear magnetic interferences in bulk silicon condensed from this gas. The NMIF silicon then permits the construction of highly sensitive quantum mechanical devices that operate using implanted nuclear magnetic isotopes of, for example, phosphorus.

In another embodiment, water vapor gas containing deuterium isotopes or tritium isotopes, as part of that vapor, can be able to be captured by means of hydrogen-bonded adducts of any of those nuclear magnetic isotopes having one or more neutrons to become retained within the atomic forcipes gallery regions, while non-neutron containing hydrogen protons are able to dissolve out of the conductive graphene component material and leave the region of the atomic forcipes as a result of diffusion. This embodiment of atomic forcipes finds use in enhancing the public safety of water-cooled nuclear reactors, as well as finding use in the cleanup of failed or breached nuclear reactor sites. Atomic forcipes containing nuclear-magnetic isotopes may then be removed for long term burial or disposal away from the biosphere where long term biological harm may result.

In one embodiment, electrically nonconductive piezoelectric particle, preferably a smectite clay lamella particle, are placed under ultrasonic activation proximal to a sheet of one atom thickness graphene particle, where one or both types of said particles are provided with any pendant Lewis base functionality to form adducts with nuclear magnetic cationic isotope species in the gap or gallery region between them.

Atomic forcipes are versatile. For example, atomic forcipes can be useful as a transceiver to wirelessly send and receive information regarding the environment of atomic forcipes. Without limitation, atomic forcipes can act as a sensor or an actuator, or both. Atomic forcipes can be configured for general use as an RFID transceiver, or a transceiver for an Internet of Things (loT) device.

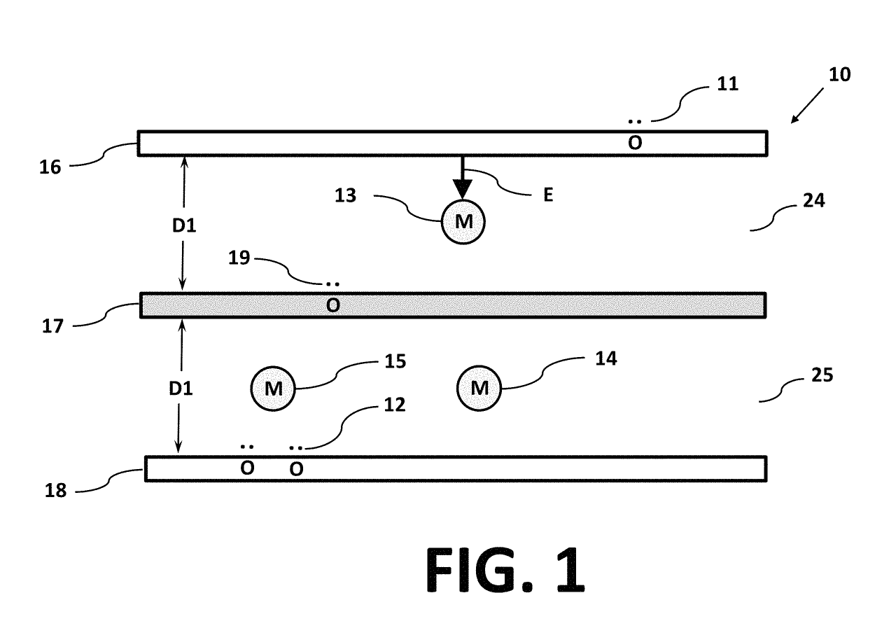

Referring now to the drawings wherein like elements are represented by like numerals throughout. In FIG. 1, a nanometer scale, trilayer atomic forcipes 10 is shown, in an edge-on view, to include a graphene sheet 17 of one carbon atom thickness, having occasional defects where a carbon atom is oxidized and replaced with an oxygen atom having a free electron base pair indicated by the two dots at 19. Graphene sheet 17 can be intercalated between clay sheets, including upper smectite clay sheet 16 having a multiplicity of exposed surface oxygen atoms with each such surface exposed oxygen atom having Lewis base electron pairs 11, and lower smectite clay sheet 18 also having a multiplicity of surface oxygen atoms with Lewis base electron pairs, represented in part by the two such oxygen atoms shown at 12. An atomic forcipes also can include a bilayer structure of a conductive graphene sheet 17 suspended as a heterostructure onto a piezoelectric insulator, such as smectite clay sheet 18. A non-nuclear-magnetic isotope atom 13 designating a cation M of positive charge, can be attracted by the inherent negative charges present in the monolithic clay sheet 16 by electric field E within the gallery region 24, 25 between sheets designated by distance D1 of a few nanometers height. Herein the exemplary ion can be magnesium, having two positive charges (Mg+2), of an isotope having atomic mass of 24 atomic mass units (AMU). Cation M 14 can be again a Mg+2 of 24 AMU, and cation M 15 can be a nuclear magnetic isotope Mg+2 of 25 AMU. Cation M of the indicated process using magnesium may be replaced in other processes by other chemical ionic species M having a chemical identity of Calcium (Ca+2), etc., each having a range of natural isotopes both non-nuclear magnetic and nuclear magnetic, where the atomic forcipes can separate out the preferred nuclear magnetic isotopes when the magnetic isotope effect is applied among otherwise chemically identical isotopes in accordance with one embodiment. Atomic forcipes also can be bilayer, i.e., formed from one conductive graphene sheet 17 and one smectite clay sheet, e.g., sheet 16 or sheet 18.

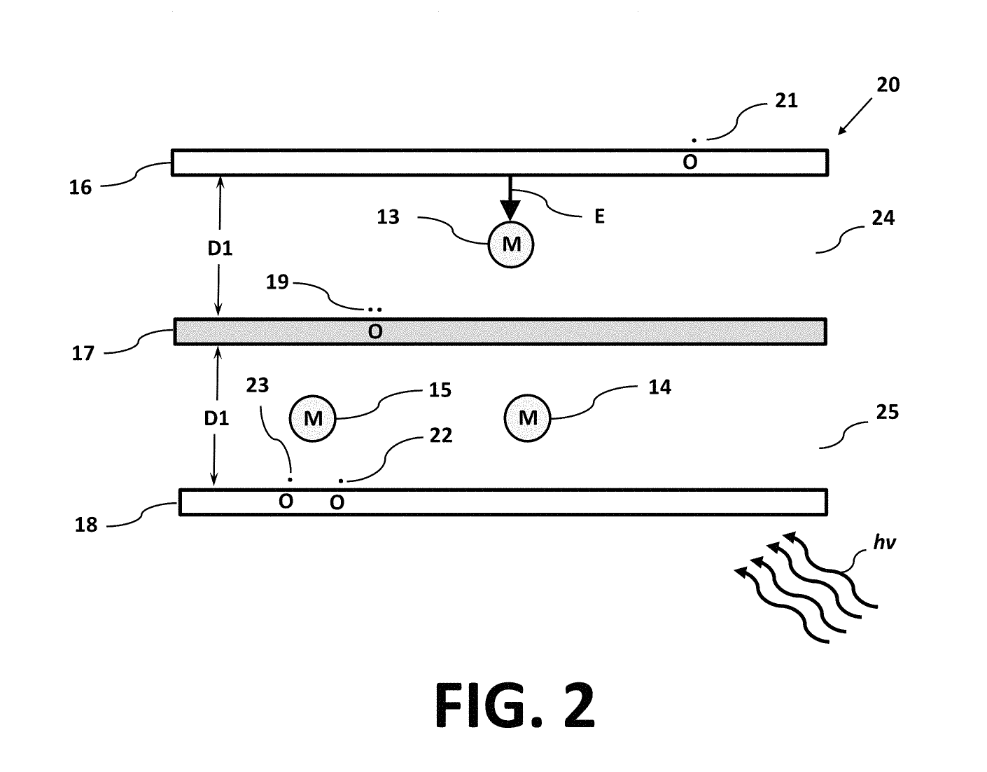

Referring now to FIG. 2 there is shown the nanometer scale atomic forcipes 10 of FIG. 1 after the introduction of high energy ultraviolet light indicated by symbol “hv” and expressed by the use of parallel wavy lines having arrows to indicate the direction of such illumination, where the passage of these rays has herein caused the removal of one of the paired electrons from some of the multiplicity of surface exposed oxygen atoms 21, 22, and 23 that are shown in an edge-on view of “free radical initiated” atomic forcipes 20, where the applied light irradiation transmits through and has interacted with some portions of graphene and smectite clay sheets. It is also understood that a multiplicity of atomic forcipes 20 typically can be used in a vapor or a solution process to separate out nuclear magnetic isotopes from a mixture containing large quantities of cations M, in accordance with one embodiment.

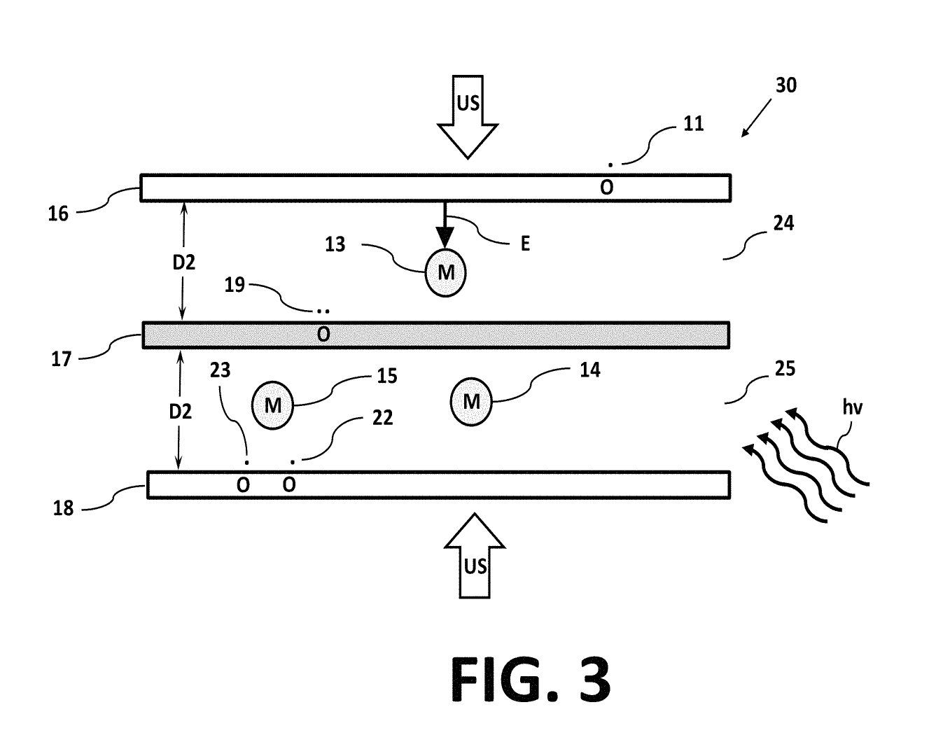

Referring now to FIG. 3 there is shown the nanometer-scale atomic forcipes 30, similar to atomic forcipes 20 of FIG. 2, after the introduction of ultrasonic energy indicated by the symbol US and a large arrow to show the direction of travel of these longitudinal phonon waves propagating parallel to this direction of energy transfer as a sequence of rarefactions and compressions applied using a chosen frequency of about 20 KHz to about 2 GHz, but can sometimes be as low as sonic phonon frequencies ranging from about 20 Hz to about 20 KHz. This phonon frequency and magnitude can depend on process variables such as the chemical reactivity of the isotope ion mixture, the temperature of the process, the atomic radius and the number of atomic charges expressed by the processed cations M, and the density of an optional solvent carrier for fluidic transport of cations M. The solvent carrier can be, without limitation, any free-radical forming solvent such as water (H2O); an alcohol such as methanol, ethanol, or isopropanol; aliphatic hydrocarbons such as hexane, heptane, or octane; or aromatic hydrocarbons, such as benzene or toluene. The process also can depend on the number of alternating repeating sheets of graphene 17, and clay 16 which in sequential addition may comprise alternative larger atomic forcipes structures of otherwise functionally equivalent embodiments as the one herein shown in an edge-on view. A multiplicity of several tens or hundreds of such stacked sheets results in considerable damping of phonon energy which may specify both frequency reduction and magnitude increase, where the primary effect and function of the sonic or ultrasonic irradiation US has momentarily and transiently reduced the representative gallery 24, 25 spacing during cyclic compression to an indicated distance of D2. This spacing reduction can result in a mutual proximal approach of indicated planar sheets 16, 17, 18 to the intercalant ions M applied during light irradiation of the indicated representative graphene and smectite clay sheets of atomic forcipes 30, such that the phonon induced repetitive oscillating pinching action in a direction normal to the plane of the sheets represents one type of actuation of these forcipes on an atomic scale, when applied in accordance with one embodiment.

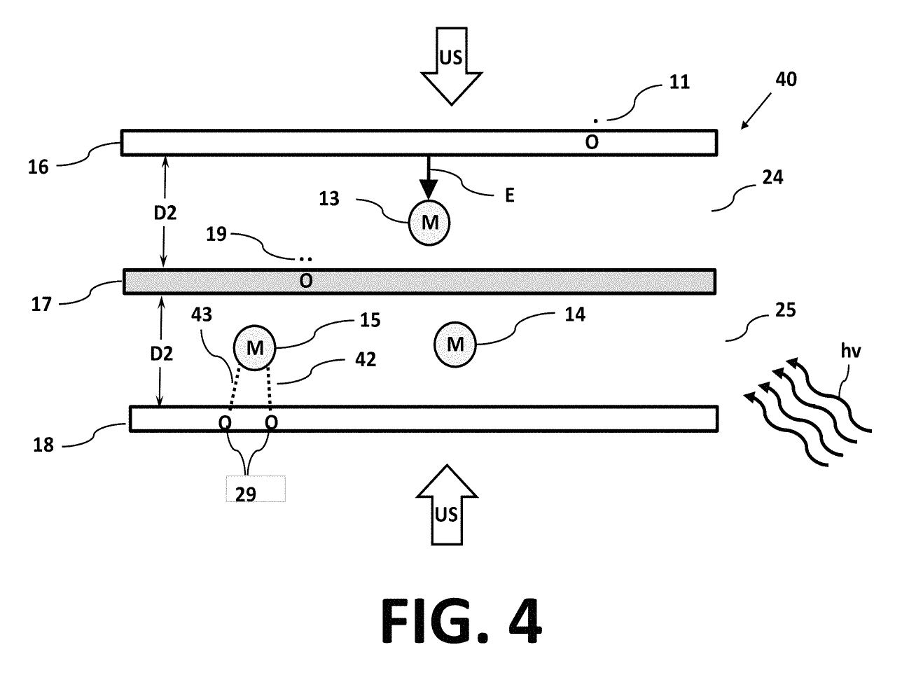

Referring now to FIG. 4, atomic forcipes 40 shows nuclear magnetic isotope M 15, reacted with a pair of oxygen atoms 29 in the substrate of the abutting clay lamina 18 by means of adducts 42, 43 having preferentially reacted under a highly confined but periodically altered geometry during ultrasonic treatment between graphene and smectite clay sheets, as the transient gap in galleries 24, 25 has reduced to the distance D2.

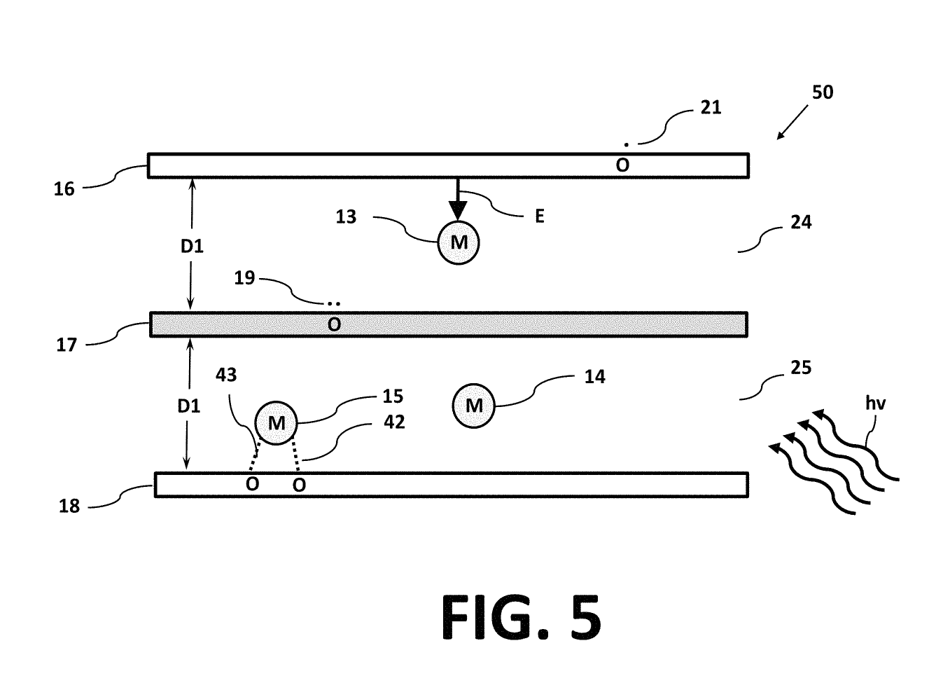

Referring now to FIG. 5 there is shown an edge-on view of atomic forcipes 50 demonstrating the adduct formed in FIG. 4, where the adduct bonds 42, 43 are maintained after ultrasonic actuation is removed and the gallery gap 24, 25 between graphene and smectite clay sheets has returned to distance D1.

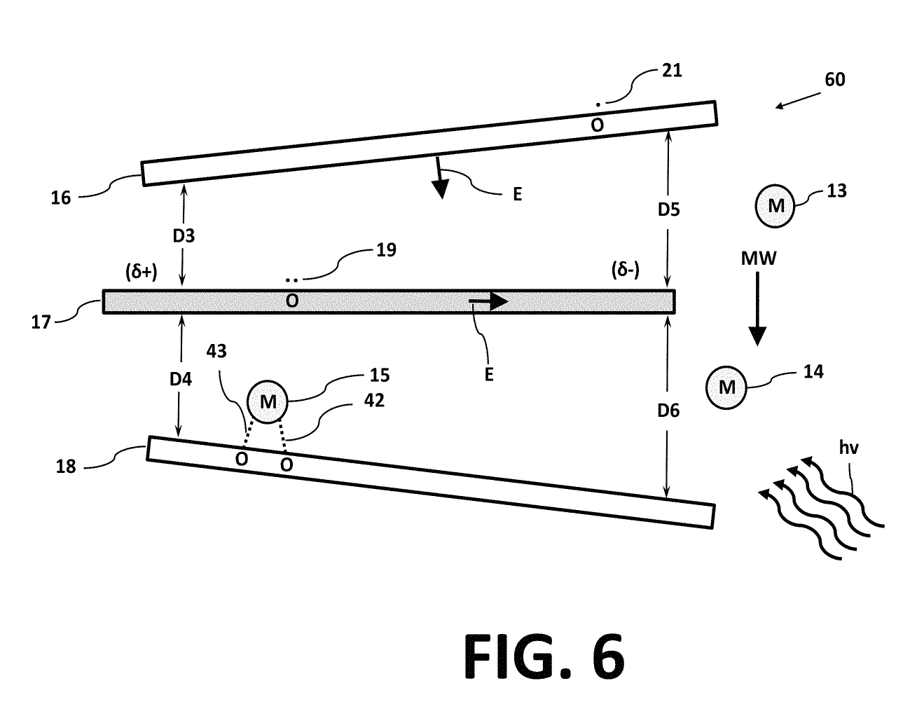

Referring now to FIG. 6 there is illustrated an edge-on view of atomic forcipes 60 showing microwave-assisted biased polarization and displacement of a graphene sheet 15, between canted smectite sheets 16 and 18, where the adduct bonds 42, 43 are maintained after microwave actuation. The induced charge difference across the graphene sheet indicated by the symbols (δ+) and (δ−) are the cause of a gallery gap reduction D3 and D4 in the presence of positive charged graphene regions, whereas the induced negative charge on the graphene sheet results in a gallery gap increase at D5 and D6. Cations 13 and 14 may now flow into the gap regions indicated by D5 and D6. Transient electric field vector E is indicated by symbol E in the plane of the graphene sheet as a result of the radio frequency (RF) of applied microwaves indicated by symbol MW adjacent to the direction of an arrow to show the direction of RF wave propagation. The static or unchanging electric field vector E is indicated by symbol E normal to the plane of the clay sheets and is represented at clay sheet 16, where the entire atomic forcipes structure 60 operates in the manner of an electromechanical pump to provide such nanometer-scale displacements, in accordance with one embodiment.

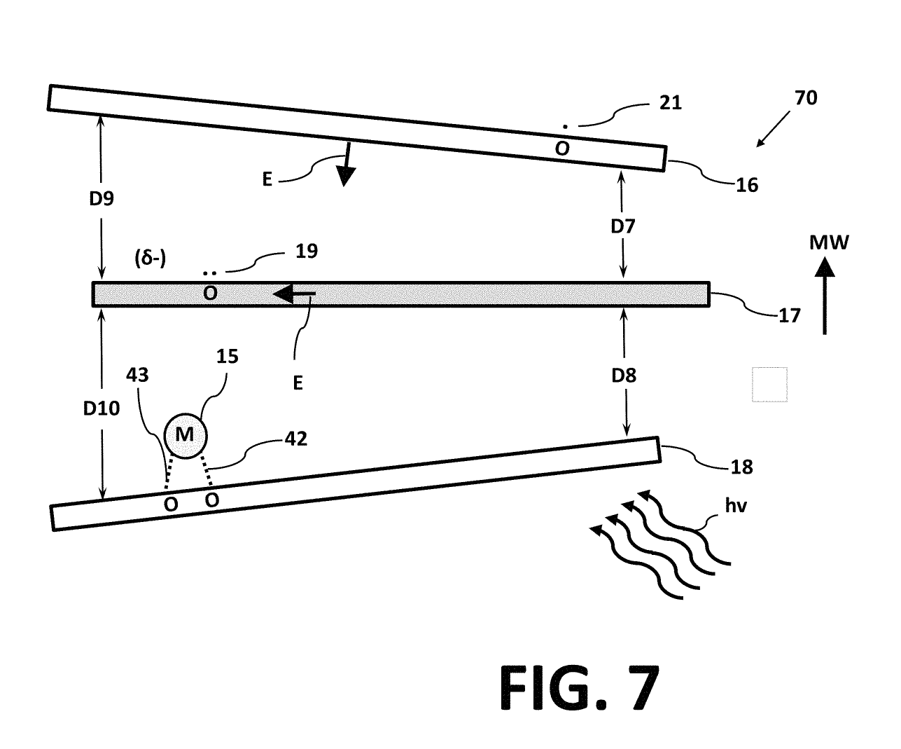

Referring now to FIG. 7, atomic forcipes 60 of FIG. 6 is shown in an edge-on view of atomic forcipes 70 demonstrating microwave-assisted alternative polarization and displacement of a graphene sheet between differently canted smectite sheets, where the direction of graphene sheet 17 polarization opposes that shown in FIG. 6, and where the transient or temporary electric field vector E within that graphene sheet 17 now opposes the direction shown in FIG. 6. A transient portion of microwave irradiative field propagation is shown by the arrow proximate to symbol MW to be pointing opposite to the one in FIG. 6. Non-bonding cations M are illustrated to be expelled from the proximal region of narrowed gaps indicated by the distances D7 and D8, where the entire atomic forcipes structure 70 operates in the manner of an electromechanical pump to provide such nanometer-scale displacements, in accordance with one embodiment.

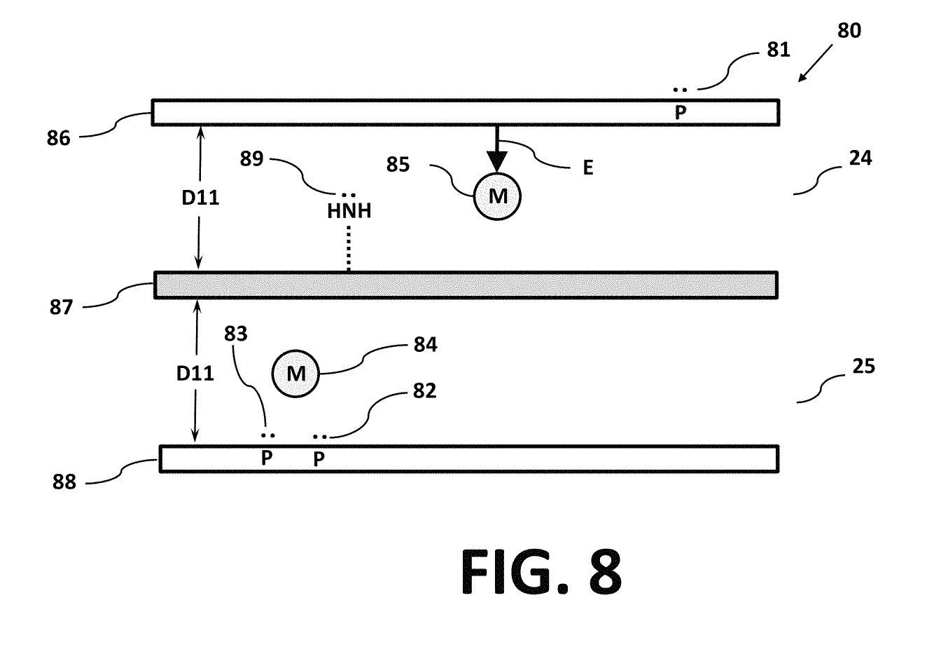

Referring now to FIG. 8 there is shown an edge-on view of atomic forcipes 80 depicting cationic intercalants M attracted to the static negative charges adjacent to clay sheets as expressed by the electric field vector E for cation M 85. Clay sheets 86 and 88 have been impacted by ion beams containing phosphorus to implant phosphorus surface impurity atoms among the oxygen atoms of the clay sheets, such that Lewis free electron pairs are expressed at the surface of these sheets by a multiplicity of phosphorus atoms 81, 82, 83. Graphene sheet 87 has been functionalized by reacting it with ammonia to form an amine moiety provided with nitrogen having a free electron pair 89. The ability of a multiplicity of such phosphorus electron pairs at 81, 82, 83, and a multiplicity of such nitrogen electron pairs 89 now provide reactive sites for the possible future formation of an unpaired electron free radical at these atomic locations, in accordance with one embodiment.

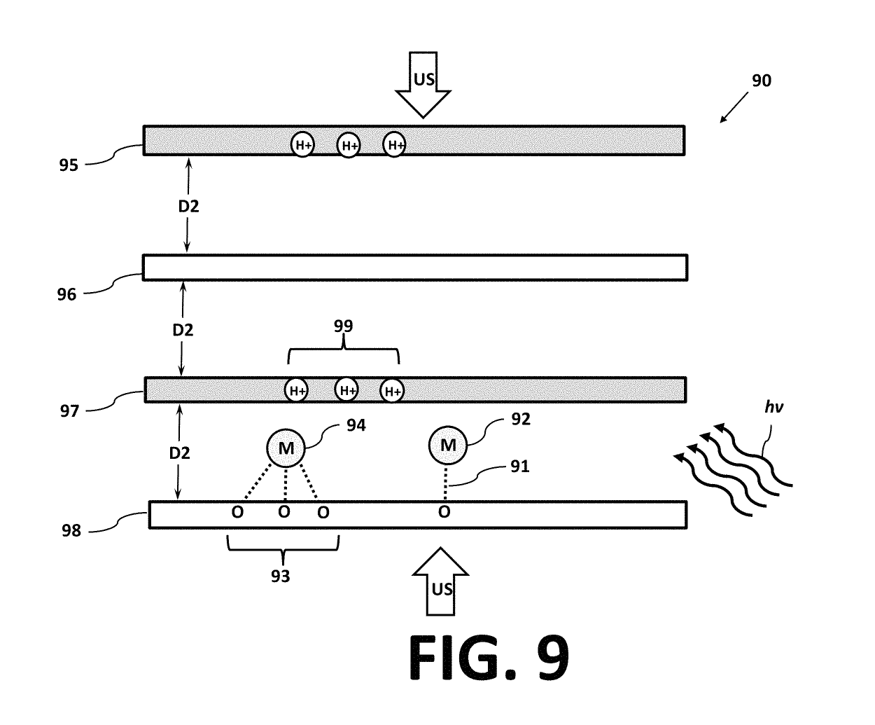

Referring now to FIG. 9 there is shown an atomic forcipes 90 exposed to ultrasound indicated by symbol US, exposed also to UV-light irradiation indicated by symbol hv, and is present in an environment having isotopes of hydrogen that result in the substantial dissolution of a multiplicity of positive charged hydrogen atoms 99 as depicted by the representative three dissolved hydrogen ions using symbols H+ in graphene sheet 97. Graphene sheet 95 has a similar population of dissolved hydrogen gas in this environment. Nuclear magnetic tritium is expressed by cation M at 92, and the adduct 91 is a hydrogen type bond with tritium to oxygen, where this tritium is substantially insoluble in graphene and ca not substantially dissolve into the indicated graphene sheets 95, 97. Nuclear magnetic deuterium likewise forms an adduct of a hydrogen type bond to oxygen, and do not substantially dissolve into graphene sheets 95, 97. Clay sheets 96 and 98 express negative charge arising within their internal structures and have oxygen surface atoms expressing free electron pairs, where three of these have formed the adduct 93 with a nuclear magnetic isotope atom selected from a periodic table group 3 cation M, 94, of valence expressing a positive 3 charge.

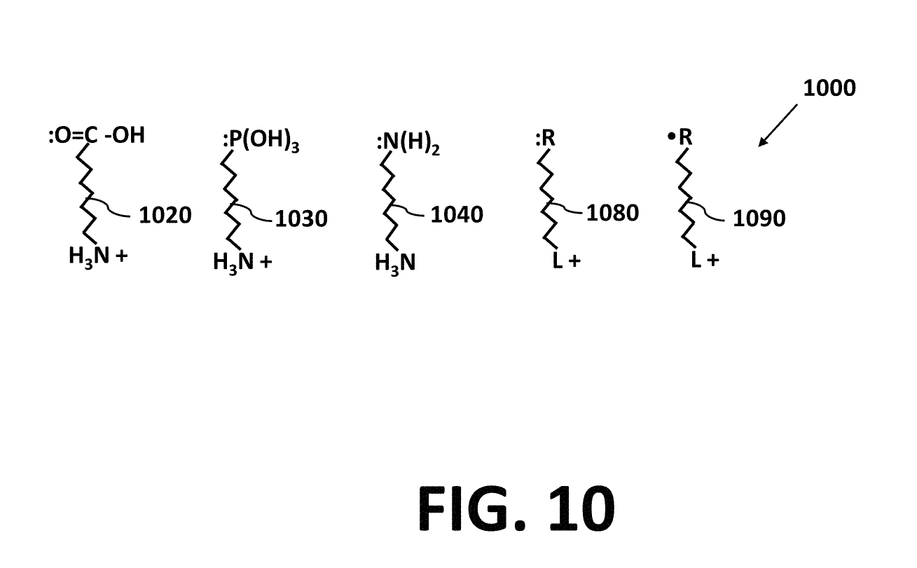

Referring now to FIG. 10 there is shown an edge-on view of organic alkyl cations having an ammonium functional group expressed by the atoms (H3N+). These positively charged molecular species at the end of an alkyl group representing a chain of carbon atoms are commonly termed alkyl-ammonium or alkonium ions, and they are used to replace natural sodium or calcium ions in common clay using an ion-exchange process. Each charge attracted replacement molecule is termed a ligand. The ammonium functional group at the lower distal end of the molecule in 1020, 1030, 1040 is therefore designated L+ in 1080 and 1090 to represent a positive charged ligand that can later be electrostatically bound to a negative charged clay surface. A carboxylic acid functional group is shown at the upper distal end of the alkyl-ammonium molecule 1020, which has a pair of Lewis electrons on oxygen. A phosphate functional group is shown at the upper distal end of the alkyl-ammonium molecule 1030 which has a pair of Lewis electrons on phosphorus. An amine functional group is shown at the upper distal end of the alkyl-ammonium molecule 1040 which has a pair of Lewis electrons on nitrogen. The upper distal functional group on molecules 1020, 1030, 1040 are representative of a class of functional groups having a pair of Lewis electrons on at least one atom in that functional group, where this class of functional groups is herein more generally represented by the symbol R in proximity to a pair of dots to represent two paired electrons, as illustrated by the molecule 1080. The loss of one electron of this pair in 1080 results in the structure represented by the molecule of 1090 such that the single dot next to the R symbol now represents a lone electron state also termed a “radical”, and indicates a dangling or partially bonded state at R which is highly reactive. Molecules 1080 and 1090 can be used to represent a multiplicity of such ligands having been ion exchanged onto sheets of doped or natural smectite clay, or attracted to oxygen containing substituents at the site of defects on graphene, and can be illustrated to reside interposed into the gallery region between planar abutting sheets, where the bulk of such ligands considerably increases the gallery distance between abutting planar sheets, thereby enhancing the exchange of mobile ions, solvent molecules, and gases into these enlarged galleries, in accordance with one embodiment.

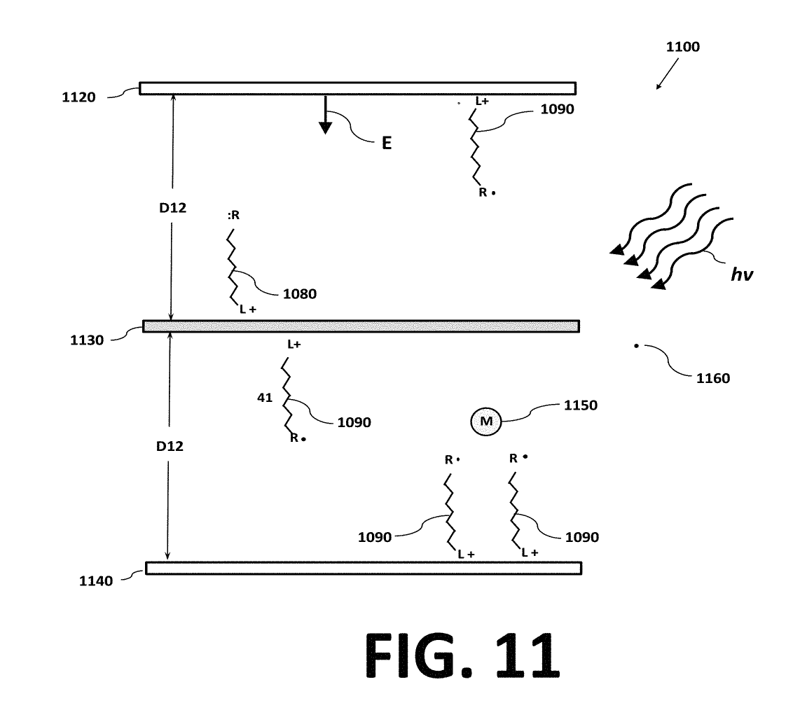

Referring now to FIG. 11 there is shown an edge-on view of atomic forcipes 1100 being irradiated by UV light expressed by a set of parallel wavy lines and the symbol hv. Static electric field vector E is shown directed normal to the plane of representative clay sheet 1120 where it is understood that such vectors can exist normal to either planar surface of each clay sheet including that of 1140. Graphene sheet 1130 is shown disposed between clay layers 1120, 1140. UV-initiated unpaired electron free radical formation can take place among intercalated organic ligands 1090. One hydrogen free radical 1160, a positive charged hydrogen atom is not dissolved into graphene, unlike the three dissolved hydrogen atoms shown in FIG. 9. Nuclear magnetic cation isotope M having positive 2 charges indicated as 1150 has easily and randomly migrated into the large gallery gap D12, in accordance with one embodiment.

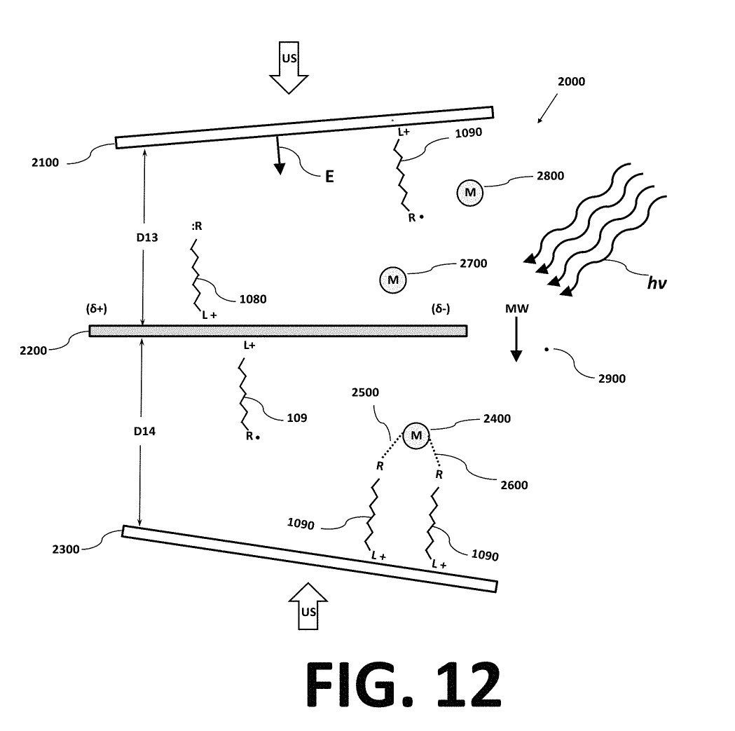

Referring now to FIG. 12 there is shown an edge-on view of atomic forcipes 2000 having a graphene sheet 2200 disposed between piezoelectric layers 2100 and 2300. In FIG. 12, forcipes 2000 can be undergoing RF polarization and inducing isotope M pumping of 2700, 2800, while under UV light irradiation free radicals are formed in aqueous solution 2900 and nuclear magnetic isotope adduct formation has been initiated at 2500, 2600 with intercalated organic cations 1090. Adduct formation is likely because of the tight packing of ligands 1090 within the constrained geometry of the gallery spaces D13 and D14 even if these express greater gaps than within galleries not exchanged with alkyl ligands. It is notable that ligands 1080, 1090 bend collectively in parallel at the charged sheet surface ligand site, indicating a reduced number of degrees of freedom compared with systems of randomly oriented reactive systems, as intended, in accordance with one embodiment.

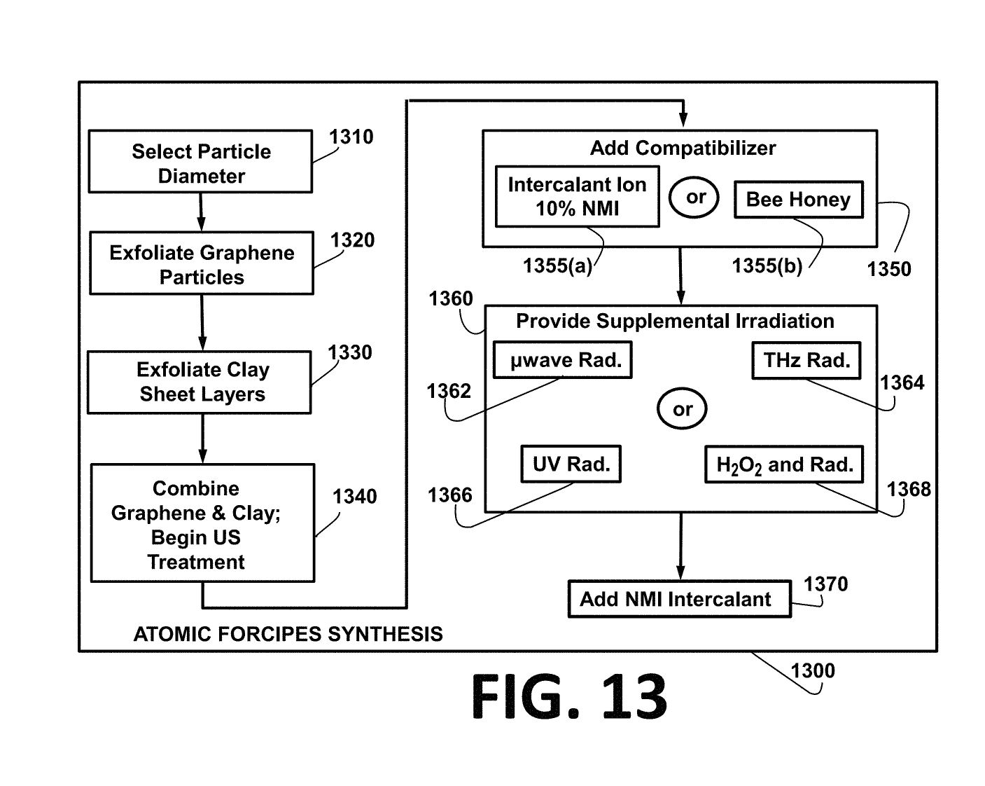

Referring to FIG. 13, an atomic forcipes synthesis method 1300 is described. Step 1310 of the synthesis is the particle diameter selection, where a typical thickness of any of these particles is about 1 nanometer and may be considered constant. The unlike nanoparticle materials are to have well matched diameters. The application or purpose of the various embodiments determine a designated diameter to achieve the appropriate function.

The cross-sectional area of atomic forcipes used as a solar radiation management metamaterial involves the synthesis to begin using particles matched in diameter and tuned to interact with the light or radio frequency wavelengths of the irradiation chosen for energy input and angular momentum near-field effect particle levitation control output. This can be achieved by starting with montmorillonite clay and natural flake graphite already sized to provide matched diameters of about 1 to 2 microns. Levitation in this context can be by photothermal energy conversion initiated by the action of lift arising from differential pressure on the particle in air. However, levitation can be in a vacuum or near vacuum by the pressure of light radiation or directional microwave radiation working against, or with, gravity. Within clouds of the earth's atmosphere, it is light that may levitate or de-levitate (depending on a direction of incident rays) using angular momentum imparted from light or microwaves.

In another example, metamaterial particles are sized to maximize interaction with Terahertz irradiation, including infrared radiation. This may be achieved by the use of commonly available smectite clay mineral particles. Some sources of Laponite have a majority of (20-25 nm) diameter particles. Laponite is a synthetic smectic clay that forms a clear, thixotropic gel when dispersed in water. Alternatively a clay having large diameter such as montmorillonite (100-150 nm) or Saponite (50-60 nm) or Hectorite (200-300 nm) is fractured using a standard ball milling process, and the particles are filtered or passed through a size exclusion sieve to provide diameters meeting the preferred diameter requirement. Alternatively, a bentonite clay is fractured using a high power ultrasonic irradiation for sufficient time to supply small diameter fragments that are sorted for a chosen diameter. Bentonite, Saponite, and Hectorite are smectite clays of the montmorillonite group.

Graphene nanodots can be purchased to already meet a narrow diameter range (20-30 nm) for the particle diameter matching requirement. Graphene nanodots are commercially available and are typically produced using an electrolytic synthesis. One source of graphene nanodots can be ACS Material, LLC, Pasadena, Calif. USA.

Step S1320 in the synthesis 1300 is to exfoliate the appropriately sized graphene particles. The Woltornist interface trapping and exfoliation process is a method of obtaining sheet layer separated single-atomic thickness graphene for the production of atomic forcipes. For the Woltornist process, see Woltornist, et al., “Properties of Pristine Graphene Composites Arising from the Mechanism of Graphene-Stabilized Emulsion Formation,” Ind. Eng. Chem. Res. 2016, 55, 6777-6782, May 25, 2016, which document is incorporated by reference herein in its entirety. In the Woltornist process, graphene separation by mild ultrasound is the result of the strong affinity of the graphene sheets to the meniscus between immiscible highly polar solvent such as water, with an equal volume of low molecular weight non-polar solvent such as hexane or heptane. Either of these solvents, when used alone, are very poor dispersion matrices for graphene, as neither one can form stable suspensions with graphene nanoparticles without the presence of a liquid-liquid interface. The interface trapping and deposition technique is simple, inexpensive, and scalable, utilizes any form of natural flake graphite or graphite nanodots with no prior treatment, and requires no post-treatments to obtain smectite sheet separation of graphitic layered raw materials. Care should be taken to use about 18 to 20 times the volume of mixed solvents to 1 volume of graphitic solid powder, or there may not be enough interfacial liquid surface area for individual sheets to remain separated in this process. However, interfacial liquid surface area can be expanded by the use of wide pans having a low liquid height to increase the effective surface of two immiscible solvents at the region of the liquid-liquid meniscus.

Step S1330 in this synthesis S1300 is the use of the Woltornist interface trapping and exfoliation process as a method of separating smectite clay sheet layers. Processing with ultrasound for about one hour obtains sheets of about 1 nanometer thickness at the polar and nonpolar solvent interface. Use of 1 part by volume of clay particles to 20 parts by volume of equal proportions of mixed polar and non-polar solvents avoids clay sheet recombination. This process is not presently used to exfoliate clay, however it is used here to provide process uniformity having no more than a few sheets of one type of particle available for interfacial reaction.

Step S1340 is to combine equal volumes of exfoliated graphene and exfoliated clay in polar and non-polar solvents, then immediately begin ultrasonic treatment of the combined mixture. The hybrid bi-layer sheets of conductive graphene particle and insulating electrostatic sheets of clay form a transient metaparticle association of atomic forcipes while ultrasound is being applied.

Step S1350, is to add compatibilizer for the particle surfaces by one of two alternative methods currently considered. In the first method 1355a, add an intercalant ion to the solution mixture containing about 10% nuclear magnetic isotope (NMI). This addition is made to the combined particles and solvents after about 10 minutes of ultrasonic treatment or when physical mixing of unlike particles appears homogeneous. The purpose of the NMI ionic intercalant is to form some hydrogen bonds at the surface of or between sheets of unlike particle materials before proceeding to step 6. This can stabilize the close association of unlike particle materials on cessation of the ultrasonic treatment. The selection of the NMI depends on the application of the embodiment. If the purpose of the atomic forcipes is to extract NMI silicon from silane, then a labile NMI ion is an appropriate compatibilizer to facilitate later ion exchange by displacement and replacement with the NMI of silicon. One NMI compatibilizer choice can be the addition of deuterium oxide (also known as heavy water) to the mixture of solvents and combined particles. Deuterated water forms a metastable hydrogen-bonded NMI capable of being removed by thermal de-bonding as heavy steam. If the purpose of the atomic forcipes is to create a solar reflectivity management material, then upper atmospheric metamaterial stability is desirable under ultraviolet irradiation, which may be achieved by the selection of natural magnesium isotope mixture to be added as a chloride salt to the combined particles until full reaction synthesis is completed. Natural magnesium contains about 10% of 31-magnesium NMI, which becomes preferentially bonded as adducts to the free radicals at the sheet surfaces.

Alternatively, step S1355(b) is the addition of up to 1% by volume of natural bee honey to the mixture of solvents and unlike particles. This addition is made to the combined particles and solvents after about 10 minutes of ultrasonic treatment or when physical mixing appears homogeneous. Natural bee honey contains both polar and non-polar components that migrate to the appropriate solvent in this mixture. This migration by solubility enables a polar charge association of the clay particle surfaces and a non-polar Van-der-Waals-type of adsorption to the surface of the graphene particles. This option is only available when residual honey contaminant is not an issue and does not detract from the chosen function of an application. For example, honey at high concentrations can interfere with clay that has been ion-exchanged with ammonium diamines by masking of pendant Lewis paired nitrogen electrons required to form adducts with nuclear magnetic isotopes.

Optional step 1360 is a supplemental irradiation process to generate large numbers of free radicals. The purpose is to provide more opportunities for adduct formation than can be achieved at the selected ultrasound irradiation. This situation may arise if low amplitude ultrasound and short process times are desired. Adduct formation by free-radicals at the solid surface enhances the proximal stability of abutting surface sheets as bilayers of unlike particle materials to form them into the stabilized atomic forcipes metamaterial particle.

The following irradiations may be used alone or in any combination:

In step S1362, the solvent mixture with unlike particles is placed into an explosion proof microwave oven and subjected to microwaves at low power (about 100 watts) for less than 1 minute.

In step S1364, alternatively, the solvent mixture with unlike particles is placed into an explosion proof Terahertz resonant cavity chamber and subjected to Terahertz radio frequency waves, for example, a coherent infrared laser light, at high power (about 400 watts) for less than about 10 minutes.

In step S1366, alternatively, the mixture is placed into a chamber having half-submerged rotating discs to expose the particle layers to ultraviolet radiation above the surface of the immiscible solvents to activate the particle surfaces with free radicals. The transparency of two-layer sheets of graphene films is as high as 95%. Care is taken to make certain that the rotating disc penetrates the liquid-liquid interface or meniscus. The disc should be able to reach the layer where unlike particles have collected, to allow these to climb the disc surface. Selection of disc material favors quartz glass because of the transparency of quartz to UV-light and the ability of graphene to temporarily adhere to quartz. The use of glass discs is possible but blocks or limits UV and reduces the amount of UV light irradiating the particles between the discs. Such UV limiting discs can be spread apart a sufficient distance for UV light to reach all exposed disc surfaces above the solvent mixture. Particle films formed on rotating discs by graphene sheet climbing are consistently 4 or fewer sheets. The films formed at the bulk solvent interface, however, can be much thicker depending on the concentration of graphite. This discrepancy arises because of the sheet climbing phenomena being driven by reduced interfacial energy between polar solvent water absorbed on the hydrophilic glass walls being displaced once graphene occupies the glass interface. Once the glass is covered, then the driving force for climbing is diminished and no additional sheets may be drawn up.

In step S1368, alternatively, hydrogen peroxide can be added to the mixture as a free radical initiator in the presence of irradiative energy. Other commercially available free radical initiators may not be used because these do not readily decay into water and oxygen, and therefore may leave contaminating residues that interfere with the function of atomic forcipes and may otherwise be difficult to remove from the gallery region of the metamaterial.

Optional synthesis step S1370 is to provide significant amounts of robustly surface-bonded NMI intercalant to the finally produced atomic forcipes. This is because the nuclear magnetic spin of high concentrations of NMI modifies the atomic forcipes out of plane flexural bending of the conductive sheet of graphene to comply with a specified frequency response as a sensor or a wireless transmitter. This synthesis is achieved for exemplary magnesium isotope mixture in one embodiment, with the understanding that another chemical identity atom type may be used in a similar synthesis. Natural magnesium chloride solution is introduced to the solvent mixture with atomic forcipes. Irradiation is allowed to proceed at low intensity and a sufficiently long irradiation time to allow diffusion of all isotopes of magnesium into the gallery region, while permitting only the non-NMI ions to exit the gallery region. The mechanism of non-NMI ion expulsion is by out of plane graphene sheet flexural flagellation in the presence of significant dynamic oscillations generated by irradiation. Such flexural energies are easily absorbed by the deformed adducts of NMI acting to absorb the energy of graphene sheet oscillation using the spin effect. The solution is then filtered to remove the particles, and the polar water solution is decanted and discarded, but replaced with fresh water and fresh dissolved magnesium chloride salt at about 1 to 10 percent concentration, not all of which is added at once. This step is repeated as often as required to displace non-NMI from the atomic forcipes gallery. Synthesis completion is determined by radio-frequency. This point is determined when the nuclear magnetic spin of high concentrations of NMI reduces the atomic forcipes out of plane flexural bending of the conductive sheet of graphene to form a substantially rigid graphene sheet that is able to absorb and re-radiate the applied radio waves. Because this synthesis step can be critical to applications with radio frequency emission functionality, a measure useful to determine reaction completion is explained in more detail as follows.

The acoustic and thermal properties of smectite or layered stacks of self-organized two-dimensional materials such as graphene or clay are extremely anisotropic. Phonons (sound energy) propagate rapidly in-plane where material modulus of the sheet is high, but much more slowly from one sheet to another across the gaps that separate sheets. The smectite structure allows anisotropic and interactive control of electromagnetic and ionic diffusion processes such as directional conductivity of energy that may be scattered between or among intra-facial ions and planar surfaces. The planar geometric anisotropy makes possible an elastodynamic wave propagation mode that leads to the precise control of wave trajectories in between the abutting sheets of metamaterials at fractional resonant wavelength nodes less than the parent excitation wavelength. Such emission can be achieved using a light laser pulse of about 800-NM or by irradiating the metamaterial with a radio-frequency pulse, then waiting for absorbance and re-emission.

An even more extreme control of an elastic wave field emitted in a thin sheet can be achieved by periodically pinning two abutting sheets at vertices of an array, such as by a honeycomb array of adducts. The result is a transformation of constructive and destructive interference at resonance of plasmon polaritons from three-fold symmetry to six fold symmetry when the incident wave is shifted by only a few nanometers, or equivalently, when the gap region between pinned plates is adjusted by a few fractions of a nanometer. The latter case may arise when the local ionic concentration is suddenly changed in the region immediately outside the region of the gap, which gives rise to a change in the density of ions inhabiting the gap region by simple diffusion. This causes a frequency shift that is a useful property in nano-antennas and nanometer-scale sensors. Therefore, the addition of magnesium chloride (as little as 1 percent) may be sufficient to change the resonant radio wave emission characteristic, wherein this transition characterizes the NMI stabilized metamaterial particles of atomic forcipes. Stabilization is an easily detected quality factor that is very sensitive to ionic concentration changes, and constitutes the ability to significantly enable RF sensing and transmitting from atomic forcipes.

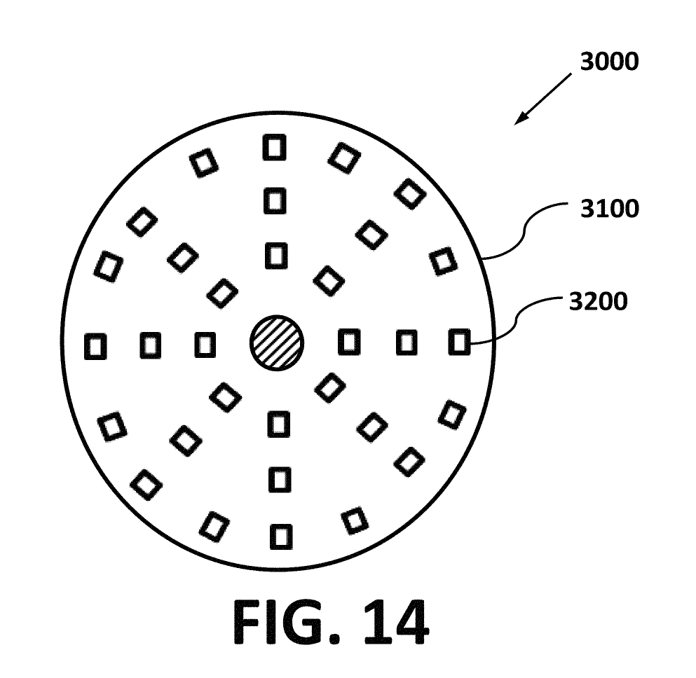

Referring now to FIG. 14 there is shown one embodiment of UV lamp 3000 made with a strong and load bearing circular printed circuit board 3100 having a multiplicity of surface mounted LEDs 3200 emitting ultraviolet radiation (UV light) that is optionally but preferably collimated or coherent in nature of emission to expedite free radical initiation among irradiated atomic species.

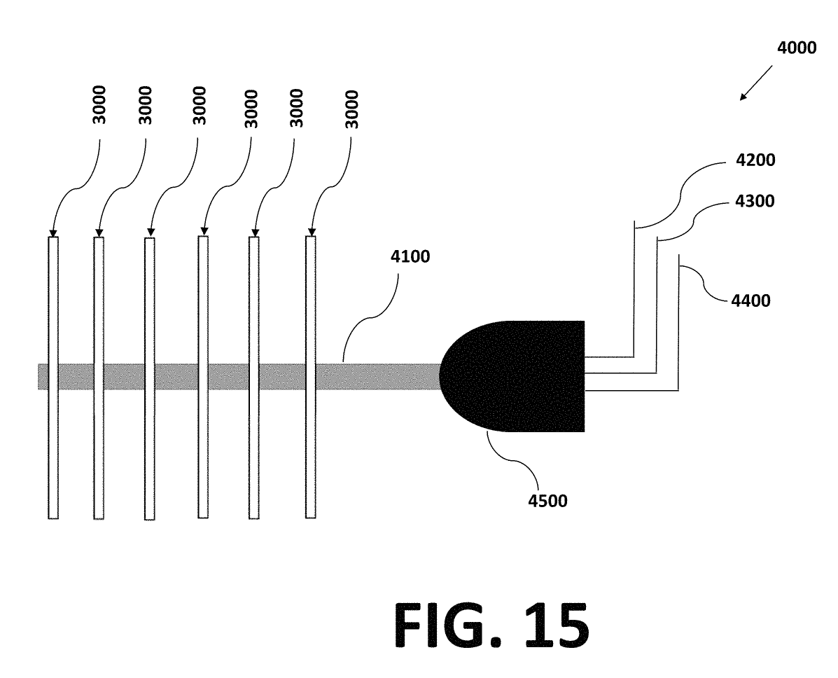

Referring now to FIG. 15 there is shown an irradiative mixer 4000 in an edge-on view of six affixed UV-LED lamps 3000 mounted to a rotating shaft 4100, wherein the rotation speed of the shaft and attached lamps of the assembly is speed controlled by a motor 4500 having electrical power supplied, for example, by electric wires 4200, 4300, 4400.

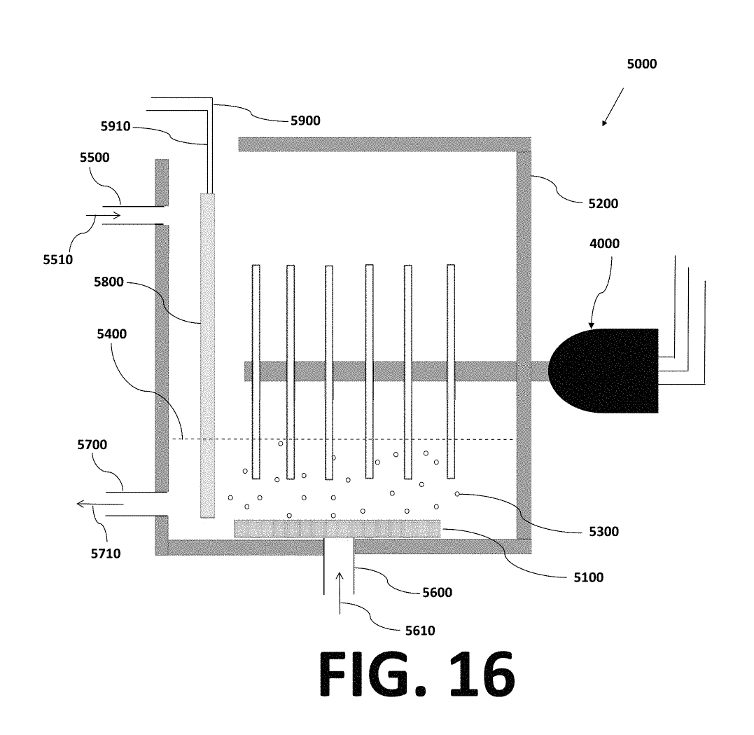

Referring now to FIG. 16, there is shown a solvent bath microwave reaction chamber, or isotope separator, 5000 having radio frequency reflecting walls 5200 and containing slurry 5300 of a multiplicity of atomic forcipes in fluid suspension. Slurry 5300 may be introduced through pipe 5500 with inlet flow 5510 to achieve a fluid level or meniscus 5400. This fluid suspension contains a multiplicity of microscopic atoms of dissolved isotopes M shown in the preceding figures such as FIG. 12. These isotopes M can be collectively lifted as a thin film to ensure penetration by the applied microwave irradiation of this process as well as by the UV light of this process to generate free radicals by means of the irradiative mixer 4000. The fluid media in bulk also can be irradiated by ultrasound using, for example, ultrasonic actuator 5800 having electric power leads 5900, 5910. Adjustable magnitudes of phonons can be delivered to the solvent bath depending on the rate of fluid exchange as the bath contents are drained by pipe 5700 containing exiting fluid 5710. Optional gas flow into the bottom of the bath 5610 may be introduced by pipe 5600 through a porous frit 5100, where such gas may be oxygen for the generation of reactive singlet oxygen, or gaseous hydrogen isotopes containing tritium or deuterium for reaction with, and removal by, the multiplicity of suspended atomic forcipes.

In another embodiment, the bath may consist of dissolved silane with a vapor above it containing gaseous silane, where the silane may be SiH4 where one hydrogen is abstracted to from the cationic free radical, or the silane may be a halogen (X) in the form of SiX4, or the like. The reaction chamber 5000 is then heated sufficiently to produce a vapor of silane while the liquid maintains a stirred suspension of silane and solid phase atomic forcipes having a multiplicity of Lewis-base donor ligands maintained in a state of ultrasonic activation. The isotope exchange reaction occurs between the liquid of silane with suspended atomic forcipes, such that adducts with nuclear magnetic isotopes of silane bond to the solid surfaces of atomic forcipes in the liquid-solid suspension. It is important that the complexing agent, atomic forcipes 5300, is solid at the separation temperature, which constrains the isotopes to be separated, and limits the geometric degrees of freedom of reactive nuclear magnetic isotopes. Thereby, nuclear magnetic silicon isotopes are exchanged to bond with the solid atomic forcipes and the non-nuclear-magnetic silicon isotopes are free to exchange to the gas side or the liquid side but not bond to the atomic forcipes. As a result, the non-nuclear magnetic isotopes are enriched in the liquid phase and the vapor phase.

Another embodiment of an isotope separator can be performed using steam as the vapor and water as the fluid medium. For example and without limitation, the non-nuclear-magnetic isotope can be hydrogen and the nuclear-magnetic isotopes can be deuterium and tritium. The type of materials being separated may require modification to the dimensions of the chamber, for example to create greater distance or otherwise a narrower chamber 5000 between the fluid suspension inlet pipe 5500 and the fluid outlet pipe 5700 that assures fresh atomic forcipes 5300 are available for the separation. Also, chamber 5000 may need a way to monitor the microwave radio frequency response of atomic forcipes 5300 to know when to introduce a greater stream of atomic forcipes into the bath, but the isotope separation may still be able to be performed.

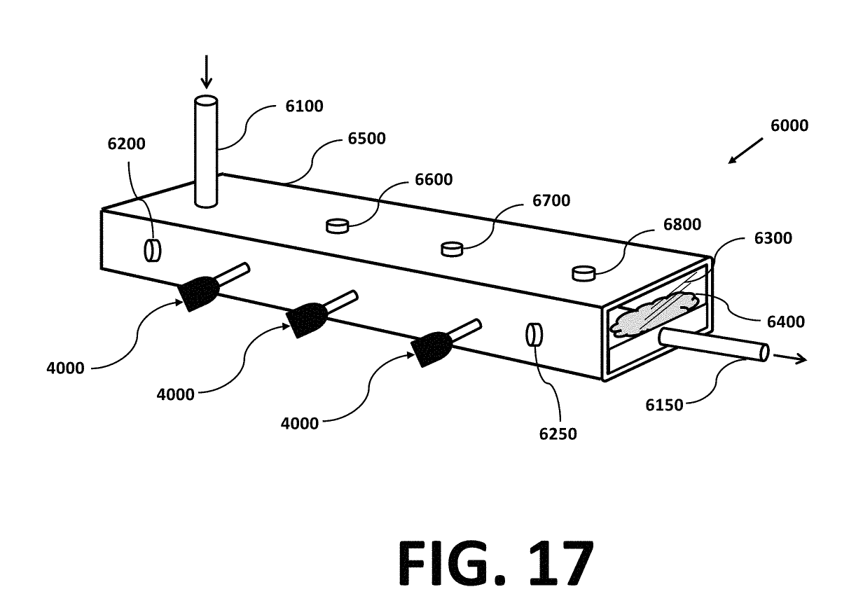

Referring now to FIG. 17 there is shown an isotope separator having fluidized atomic forcipes bed 6000 containing a floating gaseous suspension of solid particulates of atomic forcipes to separate heavy isotopes from a completely gaseous vapor stream. This vapor may be steam contaminated with undesirable deuterium and tritium isotopes from known atomic waste 6400, as seen through optional transparent observation window 6300. The fluidized bed may make use of steam with recirculating air to provide particle levitation. Microwave induction heating and irradiation are provided by programmable magnetrons 6200, 6250 of programmable intensity and duty cycle for the optimized frequency of irradiation that may use the about 2.45 GHz, the water standard microwave activation frequency. Ultrasonic activation (ultrasonication) of the levitated particles can be introduced by programmable actuators 6600, 6700, 6800, where this chamber can be used to treat water introduced as steam by pipe 6100 and removed as purified steam at outlet 6150, while solid particulate atomic forcipes are concentrated in reacted adducts with deuterium and tritium. The contaminated forcipes then can be processed for deep geologic sequestration burial in various approved types of radioactive “fallout” remediation.

Similarly, this embodiment of pure vapor treatment using a “fluidized bed” of solid particulate atomic forcipes may be used to extract the nuclear magnetic isotopes of silicon when the levitating gas can be pure SiH4, or when the levitating gas is SiXn, wherein X can be a halogen, and n may be 4. Separation of isotopes of other gaseous forms of isotope mixtures are possible using the magnetic isotope effect when atomic forcipes are used in accordance with this embodiment of an isotope separator.

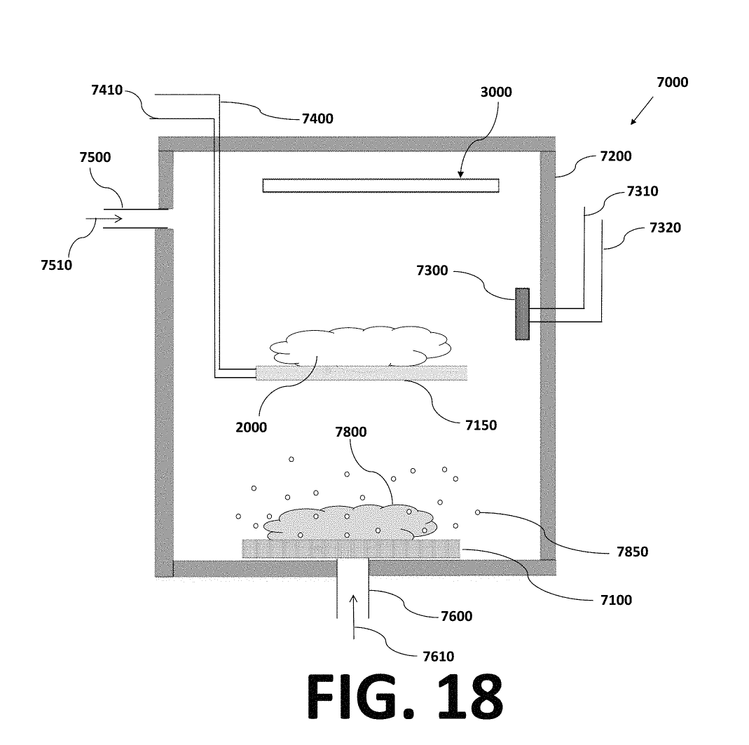

Referring now to FIG. 18 there is shown a low pressure or vacuum oven chamber 7000 reflective of radio waves, and provided with atomic forcipes powder 2000 being photonically irradiated by UV lamp 3000 and ultrasonicated by ultrasonic activator 7150 powered by electric wiring 7400, 7410, and RF irradiated by microwave radio frequencies by programmable magnetron 7300 which is powered by electricity in wires 7310 and 7320. A source of heated and vaporized isotopes is supplied at location 7800, and an optional carrier gas 7850 can be introduced to help circulate low pressure vapors introduced to the chamber at 7610 by gas feeder pipe 7600 through pressure reducer and frit 7100, in accordance with one embodiment.

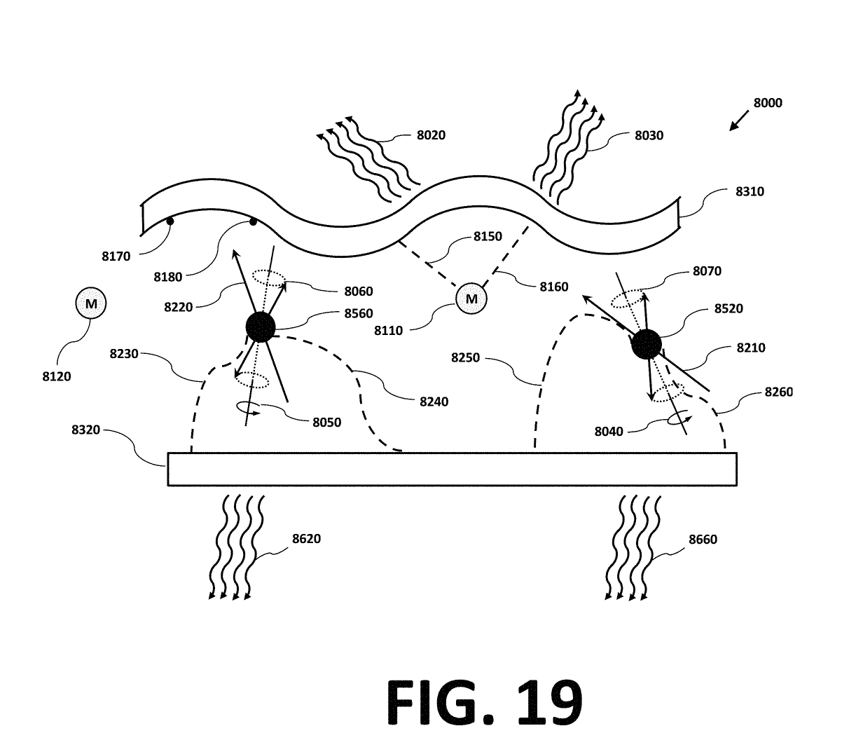

Referring now to FIG. 19 there is shown an edge-on view of graphene sheets 8000 as these are actuated by acoustic irradiation, using phonons, travelling through a solvent in which graphene is suspended. Graphene sheet 8310 expresses a wavy deformation shape characteristic of deformation by displacement above and below the plane of this sheet. Graphene sheet 8320 expresses a substantially planar geometry where deformation by local displacement has been minimized. Cation 8520 and cation 8560 are chemically identical to cation 8110.

Intercalant cations 8110, 8120 are designated by symbol M, and have an even number of neutrons in each atomic nucleus, therefore both of these cations are not a nuclear magnetic isotope (NMI). Cation 8110 is bonded to graphene sheet 8310 by hydrogen bonds 8150 and 8160, however these bonds are subject to the shearing deformation of the dynamically deforming sheet 8310 and can therefore be easily broken to from a free radical at 8150 intersection with 8300, and 8160 intersection with 8310, wherein these intersections are at the site of an impurity surface atom such as oxygen or nitrogen having unpaired electrons capable of forming free radicals. Cation 8120 expresses a charge of +2 and is free to wander away from the gallery region because it has been de-bonded by out of plane shearing forces from flexing graphene sheet 8310 and leaves behind free radicals 8170, 8180 at the site of an impurity surface atom in 8310. Sheet 8310 may also reversibly approach cation 8120 to temporarily reform a bonded adduct, however the instability of the plane of the graphene 8310 undergoing dynamic flexural deformation is likely to result in eventual ejection of dis-bonded ion 8120 to a region outside of the gallery and away from the reactive surface of graphene. Some of the energy of ultrasonic activation of 8310 results in the emission of microwave radiation 8020, 8030 from distorted regions of the dynamically deforming graphene sheet; this emission results in random constructive and destructive reinforcement as the location and direction of the out of plane deformations wander along the graphene surface, to result in poor radio frequency emission characteristics.

Intercalant cations 8520, 8560 have an odd number of neutrons in each atomic nucleus, therefore both of these cations are a nuclear magnetic isotope (NMI), and can exhibit a spin effect providing a moment of inertia to stabilize the initial nuclear orientation on the application of an electromagnetic field. Cation 8520 is bonded to graphene sheet 8310 by hydrogen bonds 8250 and 8260, and exhibits an axial magnetic spin 8040 that is normal to its local electric field 8210. The applied irradiation causes precession 8070 of cation 8520 which causes the local deformation of adduct bonds 8250, 8260 instead of the geometric deformation of graphene sheet 8320 having greater stiffness than 8250, 8260. In like manner but having a different starting orientation, cation 8560 is bonded to graphene sheet 8310 by hydrogen bonds 8230 and 8240, and exhibits an axial magnetic spin 8050 that is normal to its local electric field 8220. Current methods of directionally increasing local conduction of graphene have been unproductive. In graphene alone, researchers have used graphene nanoribbons as ‘wires’. They admit to not getting enough spin coupled electrons to propagate along their ribbons to make a useful device. Increasing conductivity can result in surface leakage current (Purcell effect), and failing to introduce the correct type of defect or geometry of defect fails to “tune” the bandgap of the plasmon to obtain the chosen wavelength of interaction. ‘Ribbon-like’ conduction effect may be achieved by the deposition of nuclear-magnetic isotopes bonded to the abutting crests of graphene in acoustic resonance. Greater concentrations of cations 8520, 8560 may extend in rows behind those shown in FIG. 19, which may produce furrows of intercalated ions. Rows of bonded intercalant NMI ions may be deliberately created within the gallery or gap between sheets by selecting an acoustic resonance mode that shepherds or accumulates concentrated regions of NMI into repeating rows to be deliberately spaced in accordance with preselected acoustic wavelength provided by ultrasonic irradiation between about 20 Hz to about 20 GHz. Adsorbed intercalant atoms can function as adatoms. An adatom is an atom that lies on a crystal surface, and can be thought of as the opposite of a surface vacancy. Adatoms can be used to keep two or more planar sheets in abutment. In embodiments, quantum spin of paramagnetic, diamagnetic, and ferromagnetic properties can work as a form of “glue.” In some embodiments, paramagnetic intercalant atoms can be used.

It is notable that the direction of 8220 is not the same as the direction of 8210. The applied irradiation causes precession 8060 of cation 8560 which causes the local deformation of adduct bonds 8230, 8240 instead of the geometric deformation of graphene sheet 8320 having greater stiffness than 8230, 8240. The random orientation of spins 8050, 8040 assures a “shock absorber” effect because the magnitude of stretch and direction of deformation of the adduct bonds 8230, 8240, 8250, 8260 are random, non-periodic, and geometrically constrained by a solid graphene surface that does not substantially deform. Adduct bonds 8230, 8240, 8250, 8260 therefore can create robust surface bonds. Substrate stabilization is the origin of the stability of the synthesis of NMI bonded to atomic forcipes. The reaction completion at the point of synthesis stabilization is tested by the substantially similar directional orientation of radio frequency radiation 8620, 8660 arising from the dynamically stabilized graphene sheet.

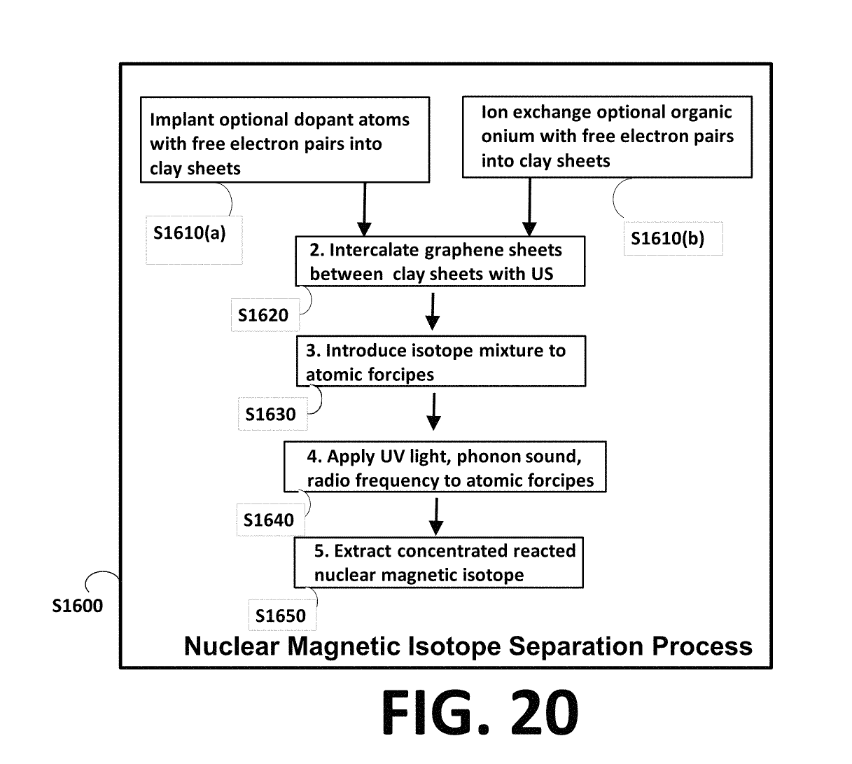

Referring now to FIG. 20 there is shown a nuclear magnetic isotope separation process S1600, implementing a solid surface geometric constraint process. Starting in step S1610(a), the method includes creating free surface radicals by subjecting a montmorillonite type of piezoelectric clay nanoparticle sheet having surface functional groups capable of losing one of the two exposed electrons present on surface atoms of implanted phosphorus or other Lewis-base type atoms, which under ultraviolet irradiation lose one electron to form surface free radicals. Alternatively, starting in step S1610(b) the method includes creating free surface radicals with a montmorillonite type of piezoelectric clay nanoparticle sheet having ion-exchanged positive charged functional groups electrostatically bonded to the silicate surface, where these groups also have a short alkyl chain ligand leading to a distal pendant functional group having with atoms expressing two exposed Lewis-base electron pairs capable of losing one electron to form a pendant free radical under ultraviolet radiation. Alternatively, a free radical initiator dissolved in a fluid allows the generation of free radicals to approach any of S1610(a) or S1610(b) to transfer a free radical onto the Lewis-base atoms of their exposed surface atoms. In step S1620, ultrasonic energy is applied to agitate and subsequently intercalate 1 atom thick sheets of polarized conductive nanoparticle graphene sheet suspended in a water and hydrocarbon solvent such as hexane having a volume to volume ratio of about 1:15, to self-assemble unlike nanoparticles into planar surface abutment with at least one of S1610(a) or S1610(b) to construct an atomic forcipes of at least 2 layers or sheets. In step S1630, the solvent phase is removed and chemically pure isotope ions are introduced into the water (aqueous) phase. In step S1640, ultrasound is then applied to the suspended particles to allow ionic intercalation, and ultraviolet light is applied to generate free radicals on these introduced ionic isotopes. This suspension is then optionally irradiated by microwaves to enhance the reactivity of the isotope ions with the atomic forcipes to create the enrichment of nuclear magnetic isotope adducts within the confined atomic forcipes structures. The slurry of suspended particles is then passed through a filter to rinse the aqueous phase and non-nuclear magnetic isotopes from the suspended solids containing atomic forcipes bonded to enriched nuclear-magnetic isotopes. An acid such as hydrochloric acid may then be used to extract (S1650) the enriched nuclear-magnetic cations from the piezoelectric montmorillonite sheets, demonstrating a fluid-based atomic forcipes nuclear magnetic isotope separation when the solid surface geometric constraint process is used. In aforementioned applications of atomic forcipes, energy is added (e.g., steam and/or irradiation) can be added to expedite isotope separation.

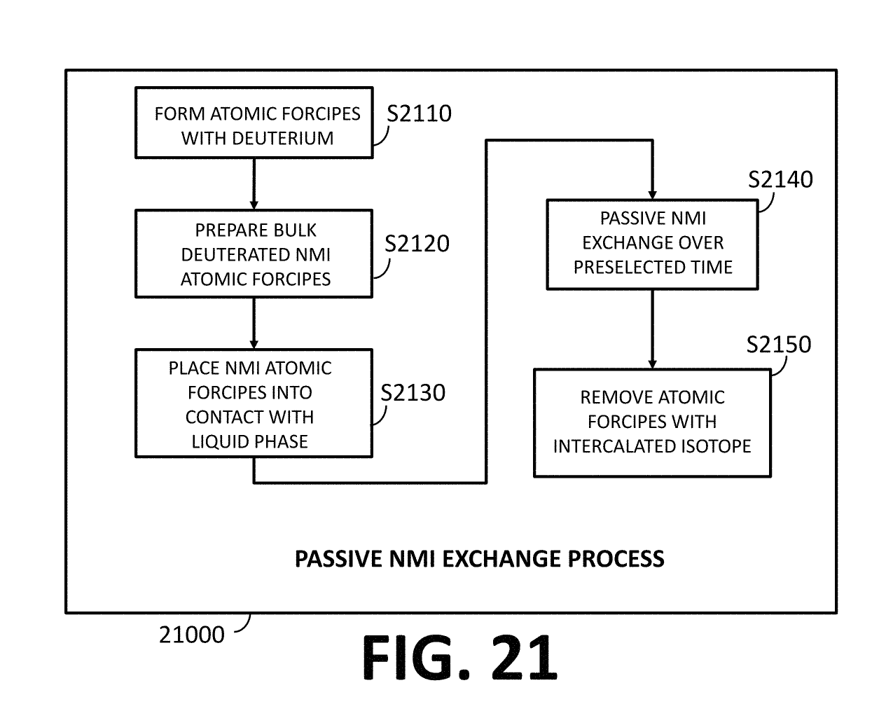

In FIG. 21, one embodiment of a passive, no-added-energy method for a isotope exchange is shown, which may trade time in place of added energy, when performing an isotope exchange. This approach may be useful, for example and without limitation, to clean the polluted groundwater from beaches surrounding FDNPP. In such an application, atomic forcipes bearing intercalated deuterium can be placed in bulk in sandbags. The sandbags can be buried beneath the sand. The sandbags may be placed at the seaward side of the briny interface with fresh water where cesium has accumulated. The addition of deuterium to the atomic forcipes makes graphene magnetic, which increases its ability to attract ferromagnetic ions, including any of those that may be radioactive isotopes in a liquid phase. Time can be used to provide the natural diffusion energy to perform isotopic sequestration. In this application, remediation is performed underground, in a cost effective manner, with little disruption to the ecosystem or public use. FIG. 21 illustrates this passive nuclear magnetic isotope exchange process 21000. In S2110, atomic forcipes can be made using an aforementioned method, intercalating deuterium, so that the graphene sheets become magnetic. The formed atomic forcipes thus made can be placed in bulk S2120 into, for example, a sandbag. The sandbags of deuterated atomic forcipes may be placed into contact with a liquid phase S2130 contaminated with a target isotope such as, for example, 137-Cesium. The contact may be made by burying sandbags with deuterated atomic forcipes, into sand or other groundwater sources. Over a preselected time, for example, 10 years or less, the sandbags remain in place, passively exposing S2140 the contaminated water with the target isotope to the deuterated atomic forcipes, forming an atomic-forcipes-isotope mixture, and yielding water without the target isotope. After the preselected time, the bags containing the contaminant can be exhumed S2150 and disposed of in a manner approved for the handling of the intercalated isotope-forcipes mixture. In addition, 137-Cesium can be used to create a dye for explosive-related materials. In such a case, the target isotope still may be useful and process 21000 can be seen as a process for harvesting the useful isotope from the environment, even if the isotope is undesirable in one sense.

As variations, combinations and modifications may be made in the construction and methods herein described and illustrated without departing from the scope of the invention, it is intended that all matter contained in the foregoing Description or shown in the accompanying Drawings shall be interpreted as illustrative rather than limiting. Various alternatives and modifications are inherent, or will become apparent to those skilled in the art after reading the foregoing disclosure. Thus, the breadth and scope of the present invention should not be limited by any of the above-described exemplary embodiments, but defined in accordance with the foregoing claims appended hereto and their equivalents. Therefore, unless such changes and modifications depart from the scope of the present invention, they should be construed as being included therein.

What is claimed is:

1. A metamaterial apparatus, comprising:
a nanomechanical magnetoelectric (ME) element having:
an insulator;
a conductive graphene sheet suspended as a heterostructure onto the insulator, wherein the conductive graphene structure has atomic-scale thickness; and
a gallery between the insulator and the conductive graphene sheet, and wherein the nanomechanical ME element comprises atomic forcipes.

2. The metamaterial apparatus of claim 1, wherein:
the insulator comprises a fractional topological insulator.

3. The metamaterial apparatus of claim 2,
wherein the atomic forcipes are acoustically-actuated, and wherein acoustic actuation further comprises: sonic waves provided to the atomic forcipes to stimulate magnetization oscillations in the graphene sheet of the atomic forcipes, wherein the sonic waves have a frequency of between about 20 Hz to about 2.0 GHz, and wherein the magnetization oscillations result in the radiation of electromagnetic waves, or
wherein the atomic forcipes are electromagnetically actuated, and wherein the electromagnetic actuation further comprises: electromagnetic waves provided to the atomic forcipes to stimulate electromagnetic oscillations in the graphene sheet of the atomic forcipes, and wherein the electromagnetic waves have a frequency of between about 2 Hz to about 500 THz.

4. The metamaterial apparatus of claim 3, wherein the sonic waves further comprise bulk acoustic waves, wherein the ME element is a ME antenna, and wherein the bulk acoustic waves stimulate magnetization oscillations of the graphene sheet resulting in the radiation of electromagnetic waves from the ME antenna.

5. The metamaterial apparatus of claim 3, wherein
the fractional topological insulator comprises a piezoelectric material.

6. The metamaterial apparatus of claim 5, wherein the piezoelectric material comprises:
a montmorillonite outer negative expressed surface charge clay sheet composition, or a magnesium hydroxide positive expressed surface charge clay sheet composition.

7. The metamaterial apparatus of claim 6, wherein the clay sheet composition comprises:
a thin film of charged, optically transparent smectite clay.

8. The metamaterial apparatus of claim 1, wherein the insulator comprises a piezoelectric material being a topological insulator having a nanometer-scale solid transition element oxide crystalline particle, wherein metal oxide impurities in the particle express a stratified internal charge opposite to a charge expressed on a particle surface, and express the photo-activity of surface charge separation, wherein electrons and holes become mobile and separable in space after irradiation by light, wherein movement of both types of charges express a preferred orientation in their quantum spin state, and wherein the preferred orientation is up or down.

9. The metamaterial apparatus of claim 8, wherein the light comprises:
an ultraviolet (UV) light.

10. The metamaterial apparatus of claim 3, wherein the graphene sheet expresses either polarization when a magnetic field is applied or magnetization when an electric field is applied, the polarization provided by charge carriers including positively charged dissolved protons and negatively charged mobile electrons, and has electrons and holes with a preselected quantum spin orientation during surface charge migration, wherein opposing charges migrate substantially into opposing longitudinal planar graphene sheet directions.

11. The metamaterial apparatus of claim 8, wherein the piezoelectric material has a transparency of greater than about 95%, has a topological insulating dielectric property, has a stratified internal charge distribution that is opposite to an expressed external surface charge, and has a photolysis-assisting chemical property.

12. The metamaterial apparatus of claim 3, wherein the conductive graphene sheet is provided with a proximal longitudinally abutting presence of at least one electrically charged lamina in a confined layer, and the conductive graphene sheet is provided with oscillating electromagnetic activation to produce oscillating structural changes in aspect ratio of the conductive graphene sheet creating an electromechanical loss, and wherein the primarily mechanical component of the electromechanical loss is converted to phonons.

13. The metamaterial apparatus of claim 3, wherein the conductive graphene sheet is provided with a proximal longitudinally abutting presence of at least one electrically charged lamina in a confined layer, and the conductive graphene sheet is provided with oscillating acoustic activation to produce oscillating physical displacement changes having a primarily dielectric energy loss, wherein the primarily dielectric energy loss results in emanated electromagnetic waves.

14. The metamaterial apparatus of claim 3, wherein the conductive graphene sheet is provided with a proximal presence of ionic nuclear magnetic isotopes in a confined geometry between surfaces of abutting sheets, and the conductive graphene sheet expressing a magnetoelectric effect is provided with oscillating electromagnetic activation or oscillating acoustic activation to produce ferroelectric coupling hysteresis, wherein ferroelectric coupling hysteresis results in an energy conversion of nuclear magnetic loss by anisotropic spin-orbit coupling, wherein a chemical potential of directionally enhanced chemical reaction rate is generated.

15. The metamaterial apparatus of claim 3, wherein the bulk acoustic waves applied to the atomic forcipes stimulate magnetization oscillations of the graphene sheet, resulting in the radiation of electromagnetic waves from the atomic forcipes.

16. The metamaterial apparatus of claim 5, wherein the piezoelectric material has a static electric field, wherein electromagnetic fields of received electromagnetic waves induce an oscillating electric field in the graphene sheet, and provide an induced electric voltage across a substantially in-plane longitudinal aspect of the graphene sheet, wherein the induced electric field oscillations react against the static electric field, causing mutually attractive and mutually repulsive mechanical forces to arise between abutting parts of the atomic forcipes, and wherein the induced electric field oscillations create phonons in proportion to the induced oscillating electric field.

17. The metamaterial apparatus of claim 13, wherein the atomic forcipes are acoustically-actuated, and further comprising:
a functional surface group having a Lewis acid or a Lewis base, the functional surface group being disposed on surfaces of the atomic forcipes, the functional surface group composed to form free radicals under UV light irradiation,
wherein the functional surface group forms a substantially stable hydrogen bond adduct with a free-radical-containing species,
wherein the free-radical-containing species includes a mixture of ionic isotopes of identical atomic number but differing atomic masses,
wherein the mixture of ionic species has at least one of the mixture of ionic isotopes expressing the magnetic isotope effect (MIE) by nuclear magnetic resonance in an electromagnetic field, and
wherein the free-radical-containing species are geometrically constrained by at least one physical solid steric barrier of the atomic forcipes, and constrained by interaction with a local intrinsic electric field present at the electrically insulating piezoelectric component of the atomic forcipes together with the local induced electric field of the electrically conductive component of the conductive abutting graphene sheet of the atomic forcipes.

18. The metamaterial apparatus of claim 17, where the free-radical-containing species comprises:
a solvated liquid;
a gaseous vapor;
an atomic cation;
an atomic anion;
a molecule having positive charge (cation);
a molecule having negative charge (anion);
a free radical;
a Lewis-base capable of reacting with a free radical; or
a Lewis-acid capable of reacting with a free radical.

19. A method for synthesizing a metamaterial apparatus, comprising:
providing enhanced graphene;
selecting layered enhanced graphene having a preselected particle size;
providing layered piezoelectric material sheets of smectite clay;
separating layered sheets of piezoelectric material into exfoliated piezoelectric material particles;
selecting piezoelectric material particles having the preselected particle size;
combining enhanced graphene particles with piezoelectric material particles into a mixture;
and
adding a compatibilizer to the mixture,
wherein atomic forcipes are formed.

20. The method of claim 19, further comprising: after combining graphene particles with piezoelectric material particles into a mixture, irradiating the mixture with ultrasound.

21. The method of claim 19, further comprising: after combining graphene particles with piezoelectric material particles into a mixture, irradiating the mixture with UV light.

22. The method of claim 19, further comprising: after combining graphene particles with piezoelectric material particles into a mixture, irradiating the mixture with microwaves.

23. The method of claim 19, wherein adding a compatibilizer further comprises:
adding an intercalant ion into the mixture; or
adding bee honey into the mixture.

24. The method of claim 19, further comprising:
providing additional irradiation to the atomic forcipes.

25. The method of claim 24, wherein providing additional irradiation further comprises one or more of:
providing microwave irradiation;
providing Terahertz radiofrequency irradiation;
providing ultraviolet irradiation; or
adding hydrogen peroxide to the atomic forcipes and providing microwave irradiation.

26. The method of claim 24, further comprising:
adding a preselected intercalant solution to the atomic forcipes.

27. The method of claim 19, wherein selecting the graphene particle size further comprises:
selecting a graphene particle having the particle size of between about 20 nanometers to about 2 microns.

28. The method of claim 20, wherein separating layered sheets of piezoelectric material into piezoelectric material particles, further comprises:
using Woltornist interface trapping and exfoliating process to obtain piezoelectric material particles; and
irradiating piezoelectric material particles with ultrasound for about 1 hour to obtain smectite clay sheet particles having a layer of about 1 nanometer thickness.

29. The method of claim 21, wherein providing graphene particles further comprises:
using the Woltornist interface trapping and exfoliating process to obtain exfoliated graphene sheets having a single atomic thickness of about 1 nanometer.

30. The method of claim 23, wherein adding an intercalant ion into the mixture further comprises:
adding an intercalant ion solution having about 10% nuclear magnetic isotope intercalant.

31. The method of claim 30, wherein the nuclear magnetic isotope intercalant comprises deuterium oxide.

32. The method of claim 23, wherein adding bee honey into the mixture, further comprises:
adding up to about 1% of bee honey to the mixture.

33. The method of claim 25, wherein:
providing microwave irradiation includes placing the mixture into a microwave oven at about 100 watts for about less than one minute; or
providing Terahertz radiofrequency irradiation at about 400 watts for less than about 10 minutes; or
providing modulated optical irradiation from infrared wavelengths to visible wavelengths.

34. The method of claim 26, wherein adding a preselected intercalant ion further comprises:
providing robustly surface bonded nuclear magnetic isotope intercalant to the atomic forcipes.

35. An isotope separator, comprising:
a low pressure oven chamber, reflective of radio waves;
atomic forcipes disposed in powder form within the oven chamber, the atomic forcipes including a piezoelectric sheet and a graphene sheet, with a gallery region therebetween;
isotope vapors within the oven chamber to react with the atomic forcipes, wherein the isotope vapors enter the oven chamber heated and vaporized, wherein there is at least one desirable isotope and at least one undesirable isotope in the isotope vapor, wherein the isotopes react with the atomic forcipes to create a forcipes-isotope mixture;
an UV lamp disposed within the oven chamber and provided to irradiate the forcipes-isotope mixture;
an ultrasonic activator disposed within the oven chamber and provided to ultrasonicate the forcipes-isotope mixture; and
a programmable magnetron disposed within the oven chamber and provided to irradiate the forcipes-isotope mixture,
wherein the second isotope is bound as an adduct to at least one sheet of the atomic forcipes, and
wherein the first isotope is released from the atomic forcipes.

36. The isotope separator of claim 35, further comprising:
carrier gas introduced into the oven chamber to circulate the isotope vapors.

37. The isotope separator of claim 35, wherein the isotope vapors comprise: water vapors having a protium isotope, and a deuterium isotope or a tritium isotope or both, wherein the second isotope is a deuterium isotope or tritium isotope, wherein hydrogen-bonded adducts of the deuterium isotope or the tritium isotope or both are retained in a gallery region of atomic forcipes, and wherein the protium isotope reversibly dissolves into and out of the graphene sheet.

38. The isotope separator of claim 35, wherein the second isotope is 29-Si, and the first isotope include 28-Si or 30-Si or both.

39. The isotope separator of claim 35, wherein the second isotope is a semiconductor dopant for ion beam implantation into silicon in a quantum mechanical logic circuit or a quantum mechanical logic device.

40. An isotope separator, comprising:
a levitated suspension of atomic forcipes;
a gaseous vapor stream in contact with and levitating the atomic forcipes, wherein the gaseous vapor stream includes a first isotope and a second isotope;
a programmable electromagnetic transducer providing actuation to the atomic forcipes by electromagnetic irradiation at a preselected frequency; and
at least one programmable ultrasonic transducer providing actuation to the atomic forcipes by ultrasonic irradiation between about 20 Hz to about 20 GHz,
wherein the second isotope is bound as an adduct to a solid surface of the atomic forcipes,
wherein the first isotope is released from the atomic forcipes and is entrained in a purified gaseous vapor stream.

41. The isotope separator of claim 40,
wherein the gaseous vapor stream is steam, the preselected frequency is between about 2.4 GHz and about 2.6 GHz, the second isotope is deuterium and tritium, and the first isotope is protium.

42. The isotope separator of claim 40,
wherein the gaseous vapor stream is one of silane (SiH4) or silicon-halogen (SiX) vapor, wherein the second isotope is 29-Si, and the first isotope include 28-Si and 30-Si.

43. A method for isotope separation, comprising:
providing a levitated suspension of atomic forcipes;
providing a gaseous vapor stream in contact with and levitating the atomic forcipes, wherein the gaseous vapor stream includes a first isotope and a second isotope;
providing kinetic activation and free radical initiation an intercalated species within the gallery of the atomic forcipes by electromagnetic irradiation at a preselected frequency;
providing actuation to the atomic forcipes by ultrasonic irradiation between about 20 Hz to about 20 GHz;
binding the second isotope as an adduct to at least one sheet of the atomic forcipes;
releasing the first isotope from the atomic forcipes; and
entraining the first isotope in a purified gaseous vapor stream.

44. The method of claim 43, wherein the gaseous vapor stream is steam, the preselected frequency is between about 2.4 GHz and about 2.6 GHz, the second isotope is deuterium or tritium or both, and the first isotope is protium.

45. The method of claim 43, wherein the gaseous vapor stream is one of silane (SiH4) or silicon-halogen (SiX), wherein the second isotope is 29-Si, and the first isotope includes 28-Si or 30-Si or both.

46. A method for isotope separation, comprising:
providing a piezoelectric nanoparticle sheet;
irradiating the piezoelectric nanoparticle sheet with ultraviolet light;
generating surface free radicals on the piezoelectric nanoparticle sheet;
providing a conductive graphene sheet;
polarizing the conductive graphene sheet to make a polarized conductive graphene sheet;
mixing the piezoelectric nanoparticle sheet with surface free radicals with the polarized conductive graphene sheet to create unlike nanoparticle suspension;
applying ultrasonic energy to unlike nanoparticle suspension;
intercalating the piezoelectric nanoparticle sheet with surface free radicals with polarized conductive graphene sheets in the suspension;
forming atomic forcipes;
creating an aqueous phase suspension with atomic forcipes;
mixing the aqueous phase suspension with nuclear magnetic isotope ions;
applying ultrasound to the suspension to promote nuclear magnetic isotope ion intercalation;
applying ultraviolet light to the suspension to generate free radicals on the isotope ions; and
extracting enriched nuclear isotope ions from the piezoelectric nanoparticle sheet in the suspension.

47. The method of claim 46, further comprising:
providing ultraviolet light to the piezoelectric nanoparticle sheet generating surface free radicals.

48. The method of claim 46, wherein the piezoelectric nanoparticle sheet comprises a montmorillonite type of piezoelectric clay nanoparticle sheet.

49. The method of claim 46, further comprising:
before extracting the enriched nuclear magnetic isotope ions, irradiating the suspension with microwaves to enhance the reactivity of the nuclear magnetic isotope ions with the atomic forcipes.

50. The method of claim 46, further comprising:
before extracting the enriched nuclear magnetic isotope ions, removing the non-nuclear magnetic isotopes.

51. A method for isotope separation, comprising:
providing piezoelectric clay sheets;
implanting atoms having Lewis-type free electron pairs into the piezoelectric clay sheets;
providing a graphene sheet;
enhancing the graphene sheet to form an enhanced graphene sheet having near-field quantum enhancement;
intercalating the enhanced graphene sheet between piezoelectric clay sheets having free electron pairs, and forming gap regions therebetween, wherein atomic forcipes are formed;
introducing an isotope mixture having a target isotope to the atomic forcipes, creating a isotope-forcipes mixture;
applying one of UV light, phonon sound, or RF energy to isotope-forcipes mixture; and
extracting concentrated reacted nuclear magnetic isotope from the isotope-forcipes mixture, the concentrated reacted nuclear magnetic isotope being the target isotope.

52. The method of claim 51, wherein implanting atoms having Lewis-type free electron pairs into the piezoelectric clay sheets further comprises one of:
implanting nuclear magnetic isotope dopant atoms with free electron pairs into the piezoelectric clay sheets; or
ion-exchanging organic onium with free electron pairs into piezoelectric clay sheets.

53. The method of claim 51, wherein enhancing graphene sheets further comprises one of:
immersing graphene sheets in a short-chain amine-containing solvent, wherein the short-chain amine-containing solvent allows a covalent bond with cations of nuclear magnetic isotopes by forming a geometrically-constrained nitrogen adducts; or
oxidizing the graphene sheets to form graphene oxide and partially reducing the graphene oxide to form reduced graphene oxide in the presence of a microwave field to leave carboxylic acid functional groups having Lewis base electron pairs, the electron pairs forming adducts with nuclear magnetic isotopes under ultrasonic activation proximate to the piezoelectric clay sheets.

54. The method of claim 52, further comprising intercalating deuterium into the gap regions wherein the graphene sheets become magnetic, wherein atomic forcipes are provided in a bulk package, wherein applying one of UV light, phonon sound, or RF energy to the isotope-forcipes mixture is replaced by providing to the isotope-forcipes mixture a preselected period of time in contact with a liquid phase, wherein the target isotope is disposed in the liquid phase, and wherein the target isotope is extracted from the liquid phase.

55. A method for isotope separation, comprising:
separating a magnetic isotope effects isotope from a non-magnetic isotope effects isotope based on nuclear spin using nuclear magnetic stiction.

56. A nanomechanical magneto-electric element, comprising:
atomic forcipes, including:
piezoelectric clay sheets, wherein the piezoelectric clay sheets have surface atoms expressing free electron pairs,
an enhanced conductive graphene sheet intercalated between the piezoelectric clay sheets, wherein the enhanced conductive graphene sheet has a near-field quantum enhancement; and
a respective gallery between each of the piezoelectric clay sheets and the enhanced conductive graphene sheet, wherein the respective gallery includes a guest intercalant ion.

57. The nanomechanical magneto-electric element of claim 56, wherein the atomic forcipes comprises a transmitting antenna or a receiving antenna.

58. The nanomechanical magneto-electric element of claim 56, wherein the atomic forcipes comprises a sensor or an actuator.

59. The nanomechanical magneto-electric element of claim 56, wherein the atomic forcipes comprises an electromechanical pump or an electrochemical pump.

60. The nanomechanical magneto-electric element of claim 56, wherein the atomic forcipes comprises a capacitance (C) and an inductance (L) from the clay and the graphene respectively, and a reactance (R) contributed by guest atomic intercalant atoms having capacitive reactance and inductive reactance, the reactance being coupled to the capacitance and the inductance, wherein a resulting LCR circuit provides dynamic oscillation frequencies.

61. The nanomechanical magneto-electric element of claim 56, further comprising:
dopant implanted into external surfaces of the piezoelectric clay sheets.

62. The nanomechanical magneto-electric element of claim 56, wherein the atomic forcipes further comprise:
piezoelectric montmorillonite insulator sheets;
atom-thick graphene sheets, wherein each of the graphene sheets is intercalated with respective piezoelectric montmorillonite insulator sheets; and
galleries, each gallery between a respective graphene sheet and a corresponding piezoelectric montmorillonite insulator sheet.

63. The nanomechanical magneto-electric element of claim 62, wherein the atomic forcipes comprise a solar radiation management apparatus using piezoelectric montmorillonite insulator sheets and atom-thick graphene sheets matched in diameter and tuned to interact with the light or radio frequency wavelengths of the irradiation chosen for energy input and angular momentum near-field effect particle levitation control output.

64. The nanomechanical magneto-electric element of claim 56, further comprising:
a nuclear magnetic isotope (NMI) disposed in a gallery, the NMI extracted from an isotope mixture, wherein NMI atomic forcipes is formed.

65. The nanomechanical magneto-electric element of claim 64, wherein the NMI atomic forcipes comprises a transceiver.

66. The nanomechanical magneto-electric element of claim 64, wherein the NMI atomic forcipes comprises a sensor, an actuator, or a tracer.

67. The nanomechanical magneto-electric element of claim 65, wherein the atomic forcipes is configured as a transceiver in an Internet of Things device.

68. The nanomechanical magneto-electric element of claim 65, wherein the atomic forcipes is configured as a RFID tag transceiver.

69. The nanomechanical magneto-electric element of claim 65, wherein the atomic forcipes are disposed in a biological entity and the transceiver is configured to communicate with a computational device external to the biological entity.
